(19) United States
(12) Patent Application Publication
(10) Pub. No.: US 2025/0089358 A1
(43) Pub. Date: Mar. 13, 2025

(54) SEMICONDUCTOR DEVICE

(71) Applicant: SUMITOMO ELECTRIC DEVICE INNOVATIONS, INC., Yokohama-shi (JP)

(72) Inventors: Takuma MORI, Yokohama-shi (JP); Fumio YAMADA, Yokohama-shi (JP)

(73) Assignee: SUMITOMO ELECTRIC DEVICE INNOVATIONS, INC., Yokohama-shi (JP)

(21) Appl. No.: 18/820,510

(22) Filed: Aug. 30, 2024

(30) Foreign Application Priority Data
Sep. 8, 2023 (JP) 2023-146218

(51) Int. Cl. H01L 27/095; H01L 29/20; H01L 29/417; H01L 29/778

(52) U.S. Cl. CPC H10D 84/86; H10D 30/475; H10D 62/8503; H10D 64/254

(57) ABSTRACT

A semiconductor device includes a substrate having a main surface and a back surface opposite to the main surface, a first transistor disposed on the main surface, a second transistor disposed on the main surface, a third transistor disposed on the main surface between the first transistor and the second transistor, a first gate line disposed on the main surface, and a back-surface metal layer disposed on the back surface.

### CROSS REFERENCE TO RELATED APPLICATIONS

This application claims priority based on Japanese Patent Application No. 2023-146218 filed on Sep. 8, 2023, and the entire contents of the Japanese patent application are incorporated herein by reference.

### FIELD OF THE INVENTION

The present disclosure relates to a semiconductor device.

### BACKGROUND OF THE INVENTION

In a field effect transistor (FET) having a finger-shaped source electrode, a finger-shaped gate electrode, and a finger-shaped drain electrode, it is known to arrange a plurality of unit FETs each having the source electrode, the gate electrode, and the drain electrode in an extending direction of the electrodes (for example, see patent literature 1: Japanese Unexamined Patent Application Publication No. 2002-299351, patent literature 2: U.S. Unexamined Patent Application Publication No. 2017/0271329, and patent literature 3: Japanese Unexamined Patent Application Publication No. 2022-135899).

### SUMMARY OF THE INVENTION

A semiconductor device according to an embodiment of the present disclosure includes a substrate having a main surface and a back surface opposite to the main surface, a first transistor disposed on the main surface, the first transistor including a first source electrode, a first drain electrode, and a first gate electrode interposed between the first source electrode and the first drain electrode in a first direction, a second transistor disposed on the main surface, the second transistor including a second source electrode, a second drain electrode, and a second gate electrode interposed between the second source electrode and the second drain electrode in the first direction, the second source electrode overlapping the first source electrode when viewed in a second direction intersecting the first direction, the second drain electrode being electrically connected to the first drain electrode, a third transistor disposed on the main surface between the first transistor and the second transistor, the third transistor including a third source electrode, a third drain electrode, and a third gate electrode interposed between the third source electrode and the third drain electrode in the first direction, the third source electrode being disposed in the first source electrode and the second source electrode when viewed in the second direction, the third source electrode being electrically connected to the first source electrode and the second source electrode, the third drain electrode being electrically connected to the first drain electrode and the second drain electrode, a first gate line disposed on the main surface and located with the third source electrode interposed between the first gate line and the third gate electrode, the first gate line being disposed in the first source electrode and the second source electrode when viewed in the second direction, the first gate line being electrically connected to the first gate electrode and the second gate electrode, and a back-surface metal layer disposed on the back surface, the back-surface metal layer being electrically connected to the first source electrode and the second source electrode via a first via hole and a second via hole, respectively, the first via hole and the second via hole overlapping the first source electrode and the second source electrode when viewed in a thickness direction of the substrate, respectively.

A semiconductor device according to an embodiment of the present disclosure includes a substrate having a main surface and a back surface opposite to the main surface, a first transistor disposed on the main surface, the first transistor including a first source electrode, a first drain electrode, and a first gate electrode interposed between the first source electrode and the first drain electrode in a first direction, a second transistor disposed on the main surface, the second transistor including a second source electrode, a second drain electrode, and a second gate electrode interposed between the second source electrode and the second drain electrode in the first direction, the second source electrode being disposed in the first source electrode when viewed in a second direction intersecting the first direction, the second source electrode being electrically connected to the first source electrode, the second drain electrode being electrically connected to the first drain electrode, a third transistor disposed on the main surface, the third transistor including a third source electrode, the first drain electrode, and a third gate electrode interposed between the third source electrode and the first drain electrode in the first direction, the third source electrode being located with the first drain electrode interposed between the third source electrode and the first gate electrode, a fourth transistor disposed on the main surface, the fourth transistor including a fourth source electrode, the second drain electrode, and a fourth gate electrode interposed between the fourth source electrode and the second drain electrode in the first direction, the fourth source electrode being disposed in the third source electrode when viewed in the second direction, the fourth source electrode being electrically connected to the third source electrode, a first gate line disposed on the main surface and located with the second source electrode interposed between the first gate line and the second gate electrode in the first direction, the first gate line being disposed in the first source electrode when viewed in the second direction, the first gate line being electrically connected to the first gate electrode, a second gate line disposed on the main surface and located with the fourth source electrode interposed between the second gate line and the fourth gate electrode in the first direction, the second gate line being disposed in the third source electrode when viewed in the second direction, the second gate line being electrically connected to the third gate electrode, a source connection line disposed on the main surface and located with the second transistor and the fourth transistor interposed between the source connection line and a transistor group including the first transistor and the third transistor, the source connection line electrically connecting the second source electrode and the fourth source electrode to each other, and a back-surface metal layer disposed on the back surface, the back-surface metal layer being electrically connected to the first source electrode, the third source electrode, and the source connection line via a first via hole, a second via hole, and a third via hole, respectively, the first via hole, the second via hole, and the third via hole overlapping the first source electrode, the third source electrode, and the source connection line when viewed in a thickness direction of the substrate, respectively.

### BRIEF DESCRIPTION OF THE DRAWINGS

FIG. 1 is a plan view of a semiconductor device according to a first embodiment.

FIG. 2 is an A-A cross-sectional view of FIG. 1.

FIG. 3 is a B-B cross-sectional view of FIG. 1.

FIG. 4 is a C-C cross-sectional view of FIG. 1.

FIG. 5 is a D-D cross-sectional view of FIG. 1.

FIG. 6 is a simplified plan view of a semiconductor device according to the first embodiment.

FIG. 7 is a plan view of a semiconductor device according to a first comparative example.

FIG. 8 is a plan view of a semiconductor device according to a second comparative example.

FIG. 9 is a plan view of a source line A in a simulation.

FIG. 10 is a plan view of a source line B in a simulation.

FIG. 11 is a diagram illustrating a source inductance Ls with respect to a unit gate width Wgu in a simulation.

FIG. 12 is a plan view of a semiconductor device according to a first modification of the first embodiment.

FIG. 13 is an A-A cross-sectional view of FIG. 12.

FIG. 14 is a B-B cross-sectional view of FIG. 12.

FIG. 15 is a C-C cross-sectional view of FIG. 12.

FIG. 16 is a plan view of a semiconductor device according to a second modification of the first embodiment.

FIG. 17 is an A-A cross-sectional view of FIG. 16.

FIG. 18 is a B-B cross-sectional view of FIG. 16.

FIG. 19 is a plan view of a semiconductor device according to a third modification of the first embodiment.

FIG. 20 is an A-A cross-sectional view of FIG. 19.

FIG. 21 is a B-B cross-sectional view of FIG. 19.

FIG. 22 is a simplified plan view of a semiconductor device according to a fourth modification of the first embodiment.

FIG. 23 is a simplified plan view of a semiconductor device according to a fifth modification of the first embodiment.

FIG. 24 is a plan view of a semiconductor device according to a second embodiment.

FIG. 25 is an A-A cross-sectional view of FIG. 24.

FIG. 26 is a B-B cross-sectional view of FIG. 24.

FIG. 27 is a plan view of a semiconductor device according to a first modification of the second embodiment.

FIG. 28 is a plan view of a semiconductor device according to a second modification of the second embodiment.

### DETAILED DESCRIPTION

In the FET, in order to improve high frequency characteristics, it is required to appropriately set a gate resistance, a source inductance, and the like.

The present disclosure has been made in view of the above problems, and an object thereof is to reduce deterioration of characteristics.

### Description of Embodiments of Present Disclosure

First, the contents of embodiments of the present disclosure will be listed and explained.

(1) A semiconductor device according to an embodiment of the present disclosure includes a substrate having a main surface and a back surface opposite to the main surface, a first transistor disposed on the main surface, the first transistor including a first source electrode, a first drain electrode, and a first gate electrode interposed between the first source electrode and the first drain electrode in a first direction, a second transistor disposed on the main surface, the second transistor including a second source electrode, a second drain electrode, and a second gate electrode interposed between the second source electrode and the second drain electrode in the first direction, the second source electrode overlapping the first source electrode when viewed in a second direction intersecting the first direction, the second drain electrode being electrically connected to the first drain electrode, a third transistor disposed on the main surface between the first transistor and the second transistor, the third transistor including a third source electrode, a third drain electrode, and a third gate electrode interposed between the third source electrode and the third drain electrode in the first direction, the third source electrode being disposed in the first source electrode and the second source electrode when viewed in the second direction, the third source electrode being electrically connected to the first source electrode and the second source electrode, the third drain electrode being electrically connected to the first drain electrode and the second drain electrode, a first gate line disposed on the main surface and located with the third source electrode interposed between the first gate line and the third gate electrode, the first gate line being disposed in the first source electrode and the second source electrode when viewed in the second direction, the first gate line being electrically connected to the first gate electrode and the second gate electrode, and a back-surface metal layer disposed on the back surface, the back-surface metal layer being electrically connected to the first source electrode and the second source electrode via a first via hole and a second via hole, respectively, the first via hole and the second via hole overlapping the first source electrode and the second source electrode when viewed in a thickness direction of the substrate, respectively. This allows a gate resistance and a source inductance to be reduced. Thus, deterioration of characteristics can be reduced.

(2) In the above (1), the semiconductor device may include a gate bus bar located with the second transistor interposed between the gate bus bar and the third transistor, the gate bus bar being electrically connected to the second gate electrode, a second gate line disposed on the main surface and located with the second drain electrode interposed between the second gate line and the second gate electrode, the second gate line being disposed in the first drain electrode and the third drain electrode when viewed in the second direction, the second gate line being electrically connected to the gate bus bar, and a third gate line disposed on the main surface, the third gate line being located between the second transistor and the third transistor and electrically connecting the first gate line and the second gate line to each other. The second drain electrode may be disposed in the first drain electrode and the third drain electrode when viewed in the second direction. This allows the gate resistance to be reduced.

(3) In the above (2), the semiconductor device may include a first drain line disposed on the main surface and configured to electrically connect the second drain electrode and the third drain electrode to each other. The third gate line may intersect the first drain line without being in contact with the first drain line and may electrically connect the first gate line and the second gate line to each other. This allows a gate potential to be supplied to the first gate line via the second gate line and the third gate line.

(4) In the above (1), the semiconductor device may include a gate bus bar located with the second transistor interposed between the gate bus bar and the third transistor, the gate bus bar being electrically connected to the second gate electrode, a second gate line disposed on the main surface, the second gate line overlapping the second drain electrode without being in contact with the second drain electrode when viewed in the thickness direction of the substrate, the second gate line being electrically connected to the gate bus bar, and a third gate line disposed on the main surface, the third gate line being located between the second transistor and the third transistor and electrically connecting the first gate line and the second gate line to each other. This allows the gate resistance to be reduced.

(5) In the above (1), the semiconductor device may include a gate bus bar located with the second transistor interposed between the gate bus bar and the third transistor, the gate bus bar being electrically connected to the second gate electrode; and a second gate line disposed on the main surface, the second gate line overlapping the second source electrode without being in contact with the second source electrode when viewed in the thickness direction of the substrate, the second gate line electrically connecting the gate bus bar and the first gate line to each other. This allows the gate resistance to be reduced.

(6) In any one of the above (1) to (5), the third transistor may include a plurality of third transistors arranged in the second direction. This allows the gate resistance to be reduced.

(7) In any one of the above (1) to (6), the semiconductor device may include a fourth transistor disposed on the main surface, the fourth transistor including the first source electrode, a fourth drain electrode, and a fourth gate electrode interposed between the first source electrode and the fourth drain electrode in the first direction, the fourth drain electrode being located with the first source electrode between the fourth drain electrode and the first gate electrode, the fourth gate electrode being electrically connected to the first gate line, a fifth transistor disposed on the main surface, the fifth transistor including the second source electrode, a fifth drain electrode, and a fifth gate electrode interposed between the second source electrode and the fifth drain electrode in the first direction, the fifth drain electrode being electrically connected to the fourth drain electrode and being located with the second source electrode interposed between the fifth drain electrode and the second gate electrode, and a sixth transistor disposed on the main surface between the fourth transistor and the fifth transistor, the sixth transistor including a fourth source electrode, a sixth drain electrode, and a sixth gate electrode interposed between the fourth source electrode and the sixth drain electrode in the first direction, the fourth source electrode being disposed in the first source electrode and the second source electrode when viewed in the second direction, the fourth source electrode being electrically connected to the first source electrode and the second source electrode, the sixth drain electrode being electrically connected to the fourth drain electrode and the fifth drain electrode, the sixth gate electrode being electrically connected to the first gate line. This allows for miniaturization.

(8) In the above (2) or (3), the semiconductor device may include a seventh transistor disposed on the main surface, the seventh transistor including a seventh drain electrode, a fifth source electrode, and a seventh gate electrode interposed between the fifth source electrode and the seventh drain electrode in the first direction, the seventh drain electrode being located with the second gate line interposed between the seventh drain electrode and the second drain electrode, the seventh drain electrode being disposed in the first drain electrode and the third drain electrode when viewed in the second direction, the seventh drain electrode being electrically connected to the first drain electrode and the third drain electrode, the fifth source electrode being located with the seventh drain electrode interposed between the fifth source electrode and the second gate line. This allows for miniaturization.

(9) A semiconductor device according to an embodiment of the present disclosure includes a substrate having a main surface and a back surface opposite to the main surface, a first transistor disposed on the main surface, the first transistor including a first source electrode, a first drain electrode, and a first gate electrode interposed between the first source electrode and the first drain electrode in a first direction, a second transistor disposed on the main surface, the second transistor including a second source electrode, a second drain electrode, and a second gate electrode interposed between the second source electrode and the second drain electrode in the first direction, the second source electrode being disposed in the first source electrode when viewed in a second direction intersecting the first direction, the second source electrode being electrically connected to the first source electrode, the second drain electrode being electrically connected to the first drain electrode, a third transistor disposed on the main surface, the third transistor including a third source electrode, the first drain electrode, and a third gate electrode interposed between the third source electrode and the first drain electrode in the first direction, the third source electrode being located with the first drain electrode interposed between the third source electrode and the first gate electrode, a fourth transistor disposed on the main surface, the fourth transistor including a fourth source electrode, the second drain electrode, and a fourth gate electrode interposed between the fourth source electrode and the second drain electrode in the first direction, the fourth source electrode being disposed in the third source electrode when viewed in the second direction, the fourth source electrode being electrically connected to the third source electrode, a first gate line disposed on the main surface and located with the second source electrode interposed between the first gate line and the second gate electrode in the first direction, the first gate line being disposed in the first source electrode when viewed in the second direction, the first gate line being electrically connected to the first gate electrode, a second gate line disposed on the main surface and located with the fourth source electrode interposed between the second gate line and the fourth gate electrode in the first direction, the second gate line being disposed in the third source electrode when viewed in the second direction, the second gate line being electrically connected to the third gate electrode, a source connection line disposed on the main surface and located with the second transistor and the fourth transistor interposed between the source connection line and a transistor group including the first transistor and the third transistor, the source connection line electrically connecting the second source electrode and the fourth source electrode to each other, and a back-surface metal layer disposed on the back surface, the back-surface metal layer being electrically connected to the first source electrode, the third source electrode, and the source connection line via a first via hole, a second via hole, and a third via hole, respectively, the first via hole, the second via hole, and the third via hole overlapping the first source electrode, the third source electrode, and the source connection line when viewed in a thickness direction of the substrate, respectively. This allows the gate resistance and the source inductance to be reduced. Thus, deterioration of the characteristics can be reduced.

(10) In the above (9), the source connection line may be disposed in an inactive region where the substrate is inactivated. This allows a parasitic capacitance to be reduced.

(11) In the above (9) or (10), the source connection line may be interposed between the first gate line and the second gate line in the first direction. This allows the gate potential to be supplied to the first gate line and the second gate line.

(12) In the above (11), the semiconductor device may include a gate bus bar located with the source connection line interposed between the gate bus bar and a transistor group including the second transistor and the fourth transistor, the gate bus bar being electrically connected to the first gate line and the second gate line. This allows the gate potential to be supplied to the gate electrode.

(13) In any one of the above (9) to (12), a width of the source connection line in the first direction may be larger than a width of the first source electrode in the first direction and a width of the third source electrode in the first direction. This allows the width of the drain electrode to be made larger than the width of the gate line.

(14) In the above (13), a width of the source connection line in the second direction may be smaller than a width of the first source electrode in the second direction and a width of the third source electrode in the second direction, a width of each of the first via hole and the second via hole in the first direction may be smaller than a width thereof in the second direction, and the width of the source connection line in the first direction may be larger than the width of the source connection line in the second direction. This allows for miniaturization.

(15) In the above (13), when viewed in the thickness direction, a number of third via holes to be connected to the source connection line and including the third via hole may be larger than a number of first via holes to be connected to the first source electrode and including the first via hole and may be larger than a number of second via holes to be connected to the third source electrode and including the second via hole. This allows the source inductance to be reduced.

### Details of Embodiments of Present Disclosure

Specific examples of a semiconductor device according to embodiments of the present disclosure will be described below with reference to the drawings. The present disclosure is not limited to these examples, but is defined by the scope of the claims, and is intended to include all modifications within the meaning and scope equivalent to the scope of the claims.

### First Embodiment

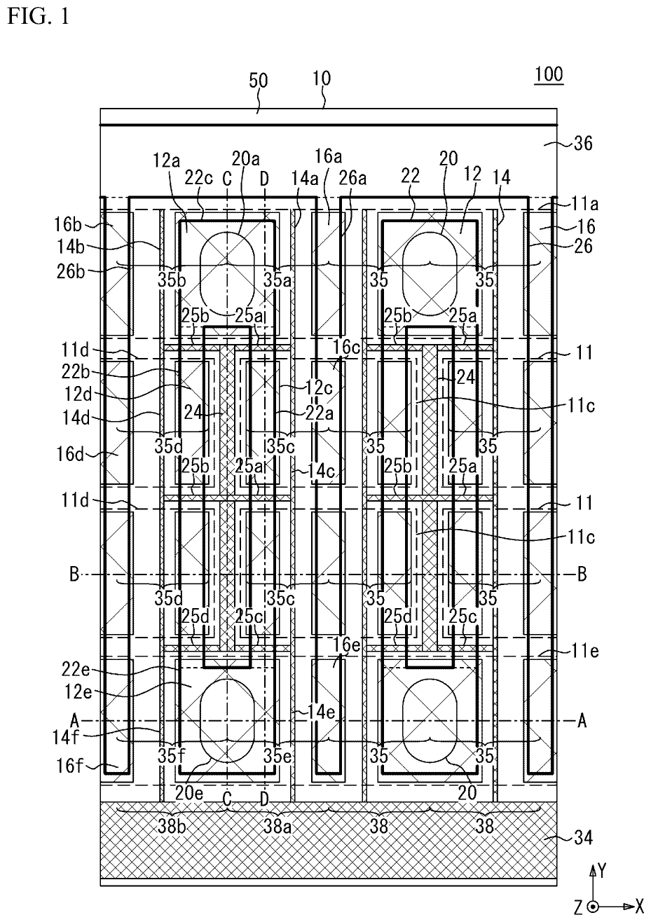

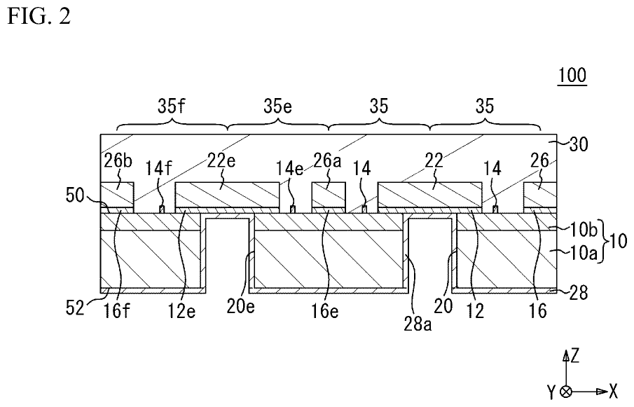

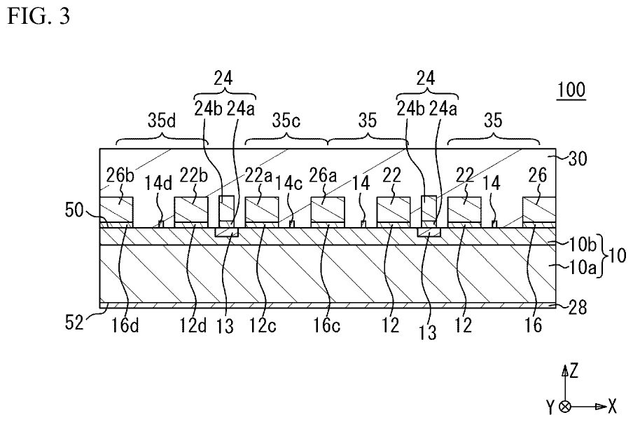

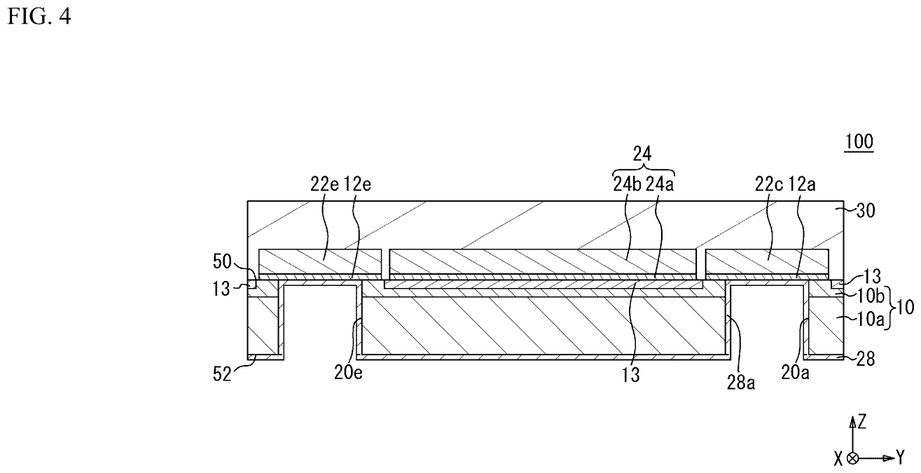

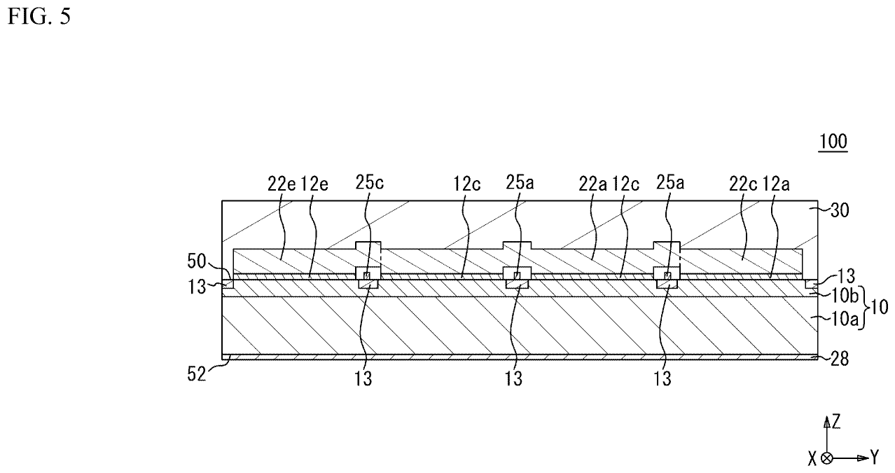

In the following, a description will be given of a semiconductor device used in an amplifier for amplifying a high-frequency signal, for example, from 0.5 GHz to 10 GHz in a base transceiver station of mobile communication as an example. FIG. 1 is a plan view of a semiconductor device according to first embodiment. FIGS. 2 to 5 are an A-A cross-sectional view, a B-B cross-sectional view, a C-C cross-sectional view and a D-D cross-sectional view, respectively, of FIG. 1. A thickness direction of a substrate 10 is referred to as a Z direction, an extending direction of a finger-shaped source electrode 12, a finger-shaped gate electrode 14 and a finger-shaped drain electrode 16 is referred to as a Y direction (second direction intersecting first direction), and an arrangement direction of source electrode 12, gate electrode 14 and drain electrode 16 is referred to as an X direction (first direction). In the plan view of FIG. 1, etc., when source electrode 12 and drain electrode 16 overlap a source line 22 and a drain line 26, it is difficult to see them. For this reason, source line 22 and drain line 26 are seen through, and thick lines indicating only an outer periphery of source line 22 and drain line 26 are illustrated inside source electrode 12 and drain electrode 16. The same applies to the following drawings.

In each figure, active regions 11, source electrodes 12, gate electrodes 14, source lines 22, drain lines 26 and transistors 35 (unit FETs) represent general elements, and active regions 11a, 11c, 11d, 11e, source electrodes 12a, 12c, 12d, 12e, gate electrodes 14a to 14f, drain electrodes 16a to 16f, source lines 22a to 22c, 22e, drain lines 26a and 26b, and transistors 35a to 35f represent specific elements included in the general elements. Transistors 35a to 35f will be mainly described below using active regions 11a, 11c, 11d, and 11e, source electrodes 12a, 12c, 12d, and 12e, gate electrodes 14a to 14f, drain electrodes 16a to 16f, source lines 22a to 22c, and 22e, and drain lines 26a and 26b.

As illustrated in FIGS. 1 to 5, in a semiconductor device 100 of first embodiment, substrate 10 has a main surface 50 and a back surface 52 opposite to main surface 50. A plurality of transistors 35 and 35a to 35f are disposed on the main surface 50 of substrate 10. Transistors 35, 35a to 35f arranged in the Y direction form transistor groups 38, 38a and 38b. In the Y direction, a drain bus bar 36 and a gate bus bar 34 are disposed on main surface 50, and sandwich transistor groups 38, 38a, and 38b.

Transistors 35 closest to drain bus bar 36 are transistors 35a and 35b. Transistors 35 closest to gate bus bar 34 are transistors 35e and 35f. Transistor 35 positioned between transistor 35a and transistors 35e is transistor 35c. Transistor 35 positioned between transistor 35b and transistor 35f is transistor 35d. Transistor group 38a includes one transistor 35a, two transistors 35c, and one transistor 35e. Transistor group 38b includes one transistor 35b, two transistors 35d, and one transistor 35f. The number of transistors 35c is one or more, and the number of transistors 35d is one or more.

Substrate 10 includes a substrate 10a and a semiconductor layer 10b disposed on substrate 10a. In an XY plane parallel to the X direction and the Y direction, a region where semiconductor layer 10b is inactivated by ion implantation or the like is an inactive region 13, and regions which are not inactivated (that is, regions where a part of substrate 10 is activated) are active regions 11a and 11c to 11e. Active regions 11a and 11e extend in the X direction. Active regions 11c and 11d are arranged in the X direction. Two active regions 11c are arranged in the Y direction, and two active regions 11d are arranged in the Y direction. Transistors 35a and 35b are disposed in active region 11a. Transistors 35c and 35d are disposed in active regions 11c and 11d, respectively. Transistors 35e and 35f are disposed in active region 11e.

Transistor 35a (first transistor) includes source electrode 12a (first source electrode), gate electrode 14a (first gate electrode), and drain electrode 16a (first drain electrode). Gate electrode 14a is interposed between source electrode 12a and drain electrode 16a in the X direction. Source electrode 12a, gate electrode 14a, and drain electrode 16a are arranged in order in the + direction of the X direction.

Transistor 35b (fourth transistor) includes source electrode 12a (first source electrode), gate electrode 14b (fourth gate electrode), and drain electrode 16b (fourth drain electrode). Source electrode 12a is interposed between drain electrode 16b and gate electrode 14a. Gate electrode 14b is interposed between source electrode 12a and drain electrode 16b in the X direction. Source electrode 12a, gate electrode 14b, and drain electrode 16b are arranged in order in the − direction of the X direction. Transistors 35a and 35b share source electrode 12a.

Transistor 35c (third transistor) includes source electrode 12c (third source electrode), gate electrode 14c (third gate electrode), and drain electrode 16c (third drain electrode). Gate electrode 14c is interposed between source electrode 12c and drain electrode 16c in the X direction. Source electrode 12c is disposed in source electrodes 12a and 12e when viewed in the Y direction. That is, source electrode 12c is not disposed outside source electrodes 12a or 12e when viewed in the Y direction. A plurality of source electrodes 12c overlap each other when viewed in the Y direction. A plurality of drain electrodes 16c overlap each other when viewed in the Y direction. Source electrode 12c, gate electrode 14c, and drain electrode 16c are arranged in order in the + direction of the X direction.

Transistor 35d (sixth transistor) includes source electrode 12d (fourth source electrode), gate electrode 14d (sixth gate electrode), and drain electrode 16d (sixth drain electrode). Source electrode 12d is located with a gate line 24 interposed between source electrode 12d and source electrode 12c, and is disposed in source electrodes 12a and 12e when viewed in the Y direction. That is, source electrode 12d is not disposed outside source electrodes 12a or 12e when viewed in the Y direction. A plurality of source electrodes 12d overlap each other when viewed in the Y direction. A plurality of drain electrodes 16d overlap each other when viewed in the Y direction. Source electrode 12d and drain electrode 16d sandwich gate electrode 14d in the X direction. Source electrode 12d, gate electrode 14d, and drain electrode 16d are arranged in order in the − direction of the X direction.

Transistor 35e (second transistor) includes source electrode 12e (second source electrode), gate electrode 14e (second gate electrode), and drain electrode 16e (second drain electrode). Gate electrode 14e is interposed between source electrode 12e and drain electrode 16e in the X direction. Source electrode 12e overlaps source electrode 12a when viewed in the Y direction. Drain electrode 16e overlaps drain electrodes 16a and 16c when viewed in the Y direction. Source electrode 12e, gate electrode 14e, and drain electrode 16e are arranged in order in the + direction of the X direction.

Transistor 35f (fifth transistor) includes source electrode 12e (second source electrode), gate electrode 14f (fifth gate electrode), and drain electrode 16f (fifth drain electrode). Source electrode 12e is interposed between drain electrode 16f and gate electrode 14e. Gate electrode 14f is interposed between source electrode 12e and drain electrode 16f in the X direction. Drain electrode 16f overlaps drain electrodes 16b and 16d when viewed in the Y direction. Source electrode 12e, gate electrode 14f, and drain electrode 16f are arranged in order in the − direction of the X direction.

Source line 22c is disposed on and in contact with source electrode 12a. Source line 22e is disposed on and in contact with source electrode 12e.

Source line 22a is disposed on and in contact with source electrode 12c. Source line 22a extends in the Y direction, electrically connects the plurality of source electrodes 12c to each other, and electrically connects the plurality of source electrodes 12c to source lines 22c and 22e. Source line 22b is disposed on and in contact with source electrode 12d. Source line 22b extends in the Y direction, electrically connects the plurality of source electrodes 12d to each other, and electrically connects the plurality of source electrodes 12d to source lines 22c and 22e.

A drain line 26a is disposed on and in contact with drain electrodes 16a, 16c, and 16e. Drain line 26a extends in the Y direction, electrically connects the plurality of drain electrodes 16a, 16c, and 16e to each other, and electrically connects the plurality of drain electrodes 16a, 16c, and 16e to drain bus bar 36. A drain line 26b is disposed on and in contact with drain electrodes 16b, 16d, and 16f. Drain line 26b extends in the Y direction, electrically connects the plurality of drain electrodes 16b, 16d, and 16f to each other, and electrically connects the plurality of drain electrodes 16b, 16d, and 16f to drain bus bar 36.

Gate line 24 (first gate line) extending in the Y direction is disposed on inactive region 13 between transistors 35c and 35d. Gate line 24 is disposed in source electrodes 12a and 12e when viewed in the Y direction. That is, gate line 24 is not disposed outside source electrode 12a when viewed in the Y direction. Gate line 24 is electrically connected to gate bus bar 34 via gate electrodes 14e and 14f. Gate line 24 includes a gate metal layer 24a disposed on substrate 10 and a wiring layer 24b disposed on and in contact with gate metal layer 24a.

Gate lines 25a extending in the X direction is disposed on inactive region 13 between transistors 35a and 35c and between transistors 35c. Gate lines 25a intersect source line 22a without being in contact with source line 22a, and electrically connect gate line 24 to gate electrodes 14a and 14c. Gate lines 25b extending in the X direction is disposed on inactive region 13 between transistors 35b and 35d and between transistors 35d. Gate lines 25b intersect source line 22b without being in contact with source line 22b, and electrically connect gate line 24 to gate electrodes 14b and 14d.

A gate line 25c extending in the X direction is disposed on inactive region 13 between transistors 35c and 35e. Gate line 25c intersects source line 22a without being in contact with source line 22a, and electrically connects gate line 24 to gate electrodes 14c and 14e. A gate line 25d extending in the X direction is disposed on inactive region 13 between transistors 35d and 35f. Gate line 25d intersects source line 22b without being in contact with source line 22b, and electrically connects gate line 24 to gate electrodes 14d and 14f. Thus, gate electrodes 14a to 14d are electrically connected to gate bus bar 34 via gate lines 24, 25a to 25d, and gate electrodes 14e and 14f.

Via holes 20a and 20e extend through substrate 10. Via holes 20a and 20e overlap source electrodes 12a and 12e, respectively, when viewed in the Z direction, and are electrically connected to source electrodes 12a and 12e, respectively. A metal layer 28 is disposed on back surface 52 of substrate 10. A metal layer 28a is disposed on an inner surface of a via hole 20. Thus, metal layer 28 (back-surface metal layer) is electrically connected to source electrodes 12a and 12e via via holes 20a (first via hole) and 20e (second via hole), respectively. Via holes 20 are not connected to source electrodes 12c or 12d. A planar shape of each of via holes 20a and 20e may be an ellipse, an oval, a rounded rectangle, or a circle.

A source potential (for example, a reference potential such as a ground potential) is supplied from metal layer 28 to source electrodes 12a and 12e via metal layer 28a in via holes 20a and 20e. Further, the source potential is supplied from source lines 22c and 22e to source electrodes 12c and 12d via source lines 22a and 22b, respectively. A gate potential (for example, a high-frequency signal and a gate bias voltage) is supplied from gate bus bar 34 to gate electrodes 14a to 14d via gate electrodes 14e and 14f, gate line 24, and gate lines 25a to 25d. A drain bias voltage is supplied from drain bus bar 36 to drain electrodes 16a to 16f via drain lines 26a and 26b. The high-frequency signals amplified in each of transistors 35a to 35f are output from drain lines 26a and 26b to drain bus bar 36.

The + ends of gate electrodes 14c and 14d in the Y direction are connected to the − ends of gate electrodes 14a and 14b in the Y direction. The + ends of gate electrodes 14c and 14d in the Y direction may not be connected to the − ends of gate electrodes 14a and 14b in the Y direction.

When semiconductor device 100 is, for example, a nitride semiconductor device, substrate 10a is, for example, a silicon carbide (SiC) substrate, a silicon (Si) substrate, a gallium nitride (GaN) substrate, or a sapphire (Al₂O₃) substrate. Semiconductor layer 10b includes a nitride semiconductor layer such as a gallium nitride layer, an aluminum gallium nitride (AlGaN) layer, and/or an indium gallium nitride (InGaN) layer. When transistors 35a to 35f are GaN HEMTs (Gallium Nitride High Electron Mobility Transistors), semiconductor layer 10b includes a gallium nitride channel layer disposed on substrate 10a and an aluminum gallium nitride barrier layer disposed on the channel layer. When semiconductor device 100 is, for example, a gallium arsenide (GaAs)-based semiconductor device, substrate 10a is, for example, a gallium arsenide substrate. Semiconductor layer 10b includes an arsenide semiconductor layer, such as a gallium arsenide layer, an aluminum gallium arsenide (AlGaAs) layer, and/or an indium gallium arsenide (InGaAs) layer. Semiconductor device 100 may be a silicon semiconductor device such as a laterally diffused metal oxide semiconductor (LDMOS).

Source electrodes 12a, 12c, 12d, and 12e and drain electrodes 16a to 16f are metal films, and each of them includes, for example, a titanium film and an aluminum film stacked in this order from substrate 10. Gate electrodes 14a to 14f and gate metal layer 24a are metal films, and each of them includes, for example, a nickel film and a gold film stacked in this order from substrate 10. Source lines 22a to 22c and 22e, drain lines 26a and 26b, wiring layer 24b, metal layers 28 and 28a, and drain bus bar 36 are, for example, a gold layer, a copper layer, or an aluminum layer. An insulating layer 30 disposed on substrate 10 so as to cover transistors 35a to 35f is, for example, an organic insulating layer such as a polyimide layer or a benzocyclobutene (BCB) layer.

A width of source electrodes 12a and 12e in the X direction is, for example, 50 μm to 150 μm. A width of source electrodes 12c and 12d in the X direction is, for example, 5 μm to 20 μm. A gate length of gate electrodes 14a to 14f in the X direction is, for example, 0.25 μm to 2 μm. A width of drain electrodes 16a to 16f in the X direction is, for example, 5 μm to 150 μm. A width of gate line 24 in the X direction is, for example, 5 μm to 20 μm. A width of gate lines 25a to 25d in the Y direction is, for example, 3 μm to 20 μm. For reducing the gate resistance, the width of gate line 24 in the X direction and the width of gate lines 25a to 25d in the Y direction are larger than the gate length and, for example, two times or more of the gate length. A gate width of transistors 35a to 35f in the Y direction is, for example, 100 μm to 400 μm. A width of via holes 20a and 20e in the X direction is, for example, 10 μm to 60 μm.

The widths of source lines 22a to 22c and 22e and drain lines 26a and 26b in the X direction are the same as or slightly smaller than the widths of source electrodes 12a, 12c, 12d, and 12e and drain electrodes 16a and 16d in the X direction, respectively. The thicknesses of source lines 22a to 22c and 22e and drain lines 26a and 26b are, for example, 1 μm to 20 μm.

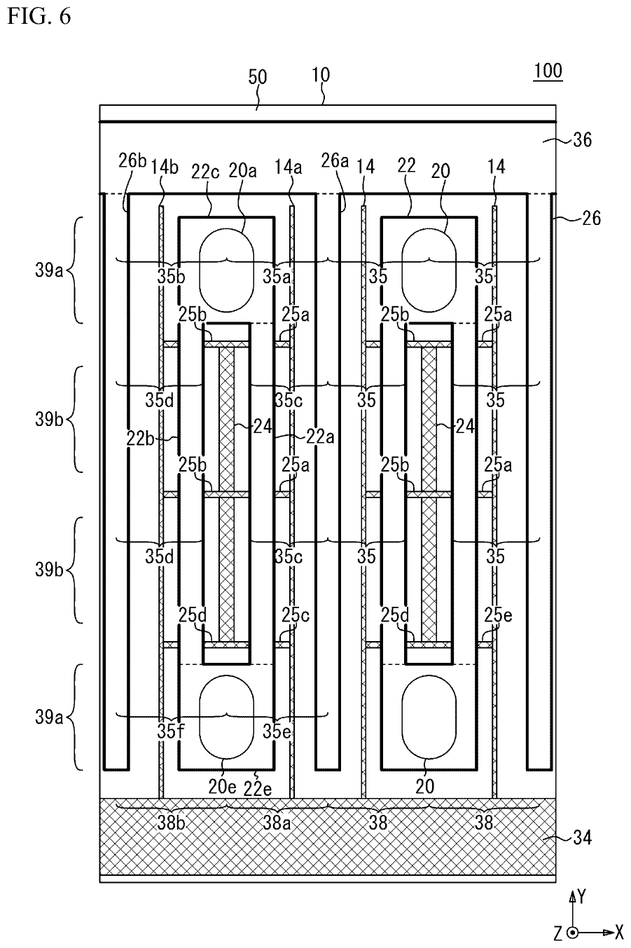

FIG. 6 is a simplified plan view of a semiconductor device according to the first embodiment. In FIG. 6, active regions 11, source electrodes 12, and drain electrodes 16 are not illustrated. Transistors 35 arranged in the X direction are referred to as transistor groups 39a and 39b. In transistor group 39a, a source electrode is shared by transistor 35a (and 35e) and transistor 35b (and 35f), and via hole 20a (and 20e) is provided. In transistor group 39b, gate line 24 is disposed between transistors 35c and 35d. The transistor group closest to drain bus bar 36 is transistor group 39a, and the transistor group closest to gate bus bar 34 is transistor group 39a.

### First Comparative Example

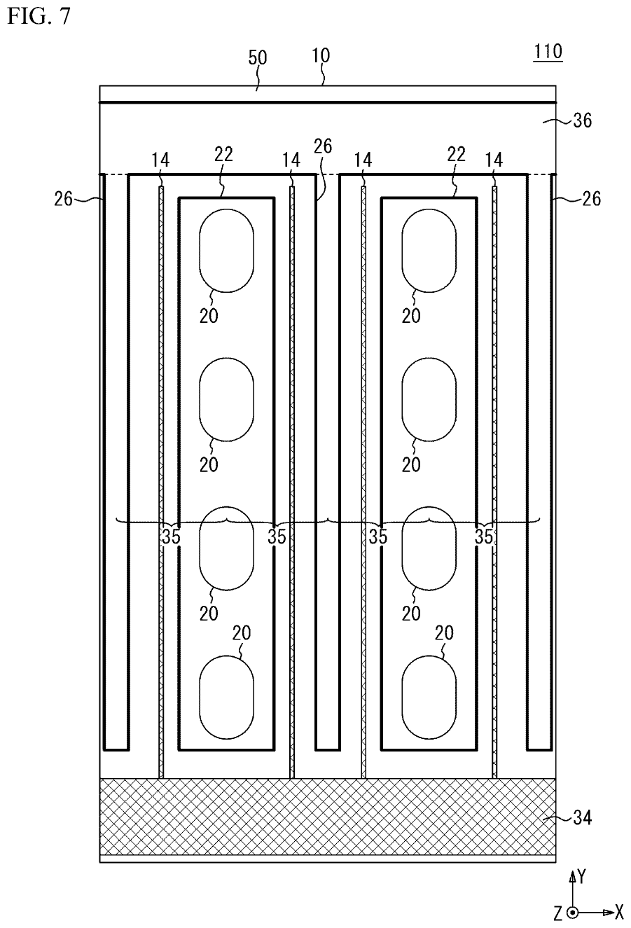

A first comparative example is an example of a multi-finger type FET. FIG. 7 is a plan view of a semiconductor device according to the first comparative example. As illustrated in FIG. 7, a semiconductor device 110 of the first comparative example is not provided with gate lines 24 and 25a to 25d. Gate electrode 14 extends in the Y direction and is electrically connected directly to gate bus bar 34. Via hole 20 is directly provided in the source electrode.

### Second Comparative Example

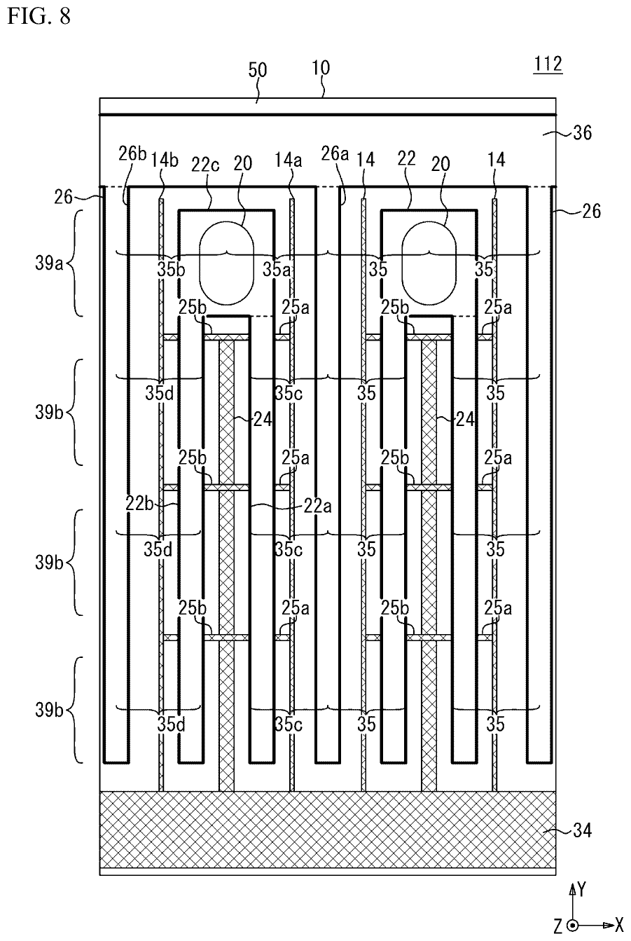

FIG. 8 is a plan view of a semiconductor device according to a second comparative example. As illustrated in FIG. 8, in a semiconductor device 112 of the second comparative example, the transistor group closest to gate bus bar 34 is transistor group 39b, and gate line 24 is electrically connected directly to gate bus bar 34. The other configurations are the same as those of the first embodiment.

In the first comparative example, the source electrode is provided with via hole 20, and thus the source inductance can be reduced. However, since gate electrode 14 is long, the gate resistance increases.

In the second comparative example, the gate resistance can be made smaller than in first comparative example because gate lines 24, 25a, and 25b are provided. However, the source electrodes of transistors 35c and 35d are supplied with the source potential from metal layer 28 via via hole 20 and source lines 22c, 22a, and 22b. Thus, the source inductance of the second comparative example is larger than that of first comparative example.

In second comparative example, in order to reduce the gate resistance and the source inductance, it is considered to reduce the width between drain bus bar 36 and gate bus bar 34 in the Y direction. However, in this case, when the saturation power is increased while securing a desired gate width, the width of the semiconductor chip in the X direction in which the semiconductor device is provided is increased. This reduces a ratio of the width of the semiconductor chip in the Y direction to the width of the semiconductor chip in the X direction. This is not practical because the semiconductor chip is easily broken.

### [Simulation]

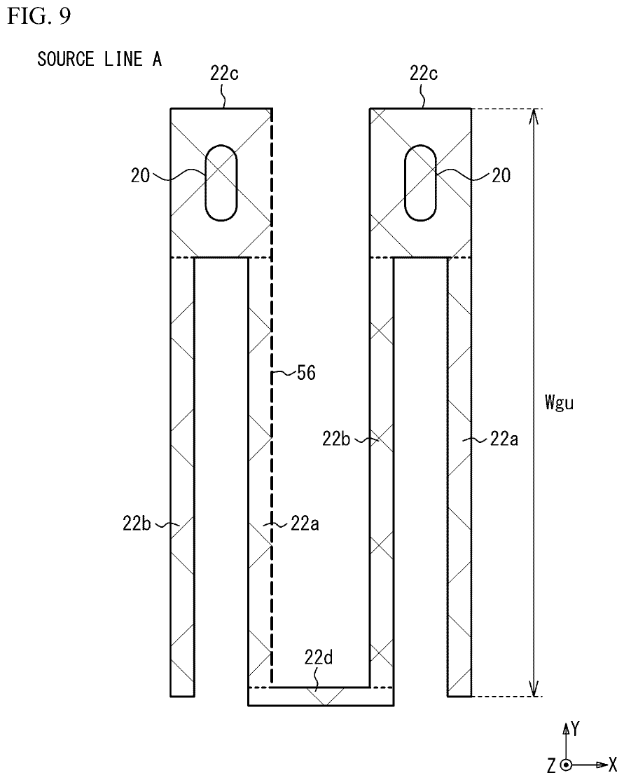

The source inductance of the source line in second comparative example and first embodiment was simulated. A source line A is the source line of second comparative example. FIG. 9 is a plan view of source line A in the simulation. As illustrated in FIG. 9, in source line A, source lines 22a and 22b extend from source line 22c in the − direction in the Y direction. Source lines 22a and 22b are electrically connected to each other by a source line 22d at − ends of source lines 22a and 22b in the Y direction.

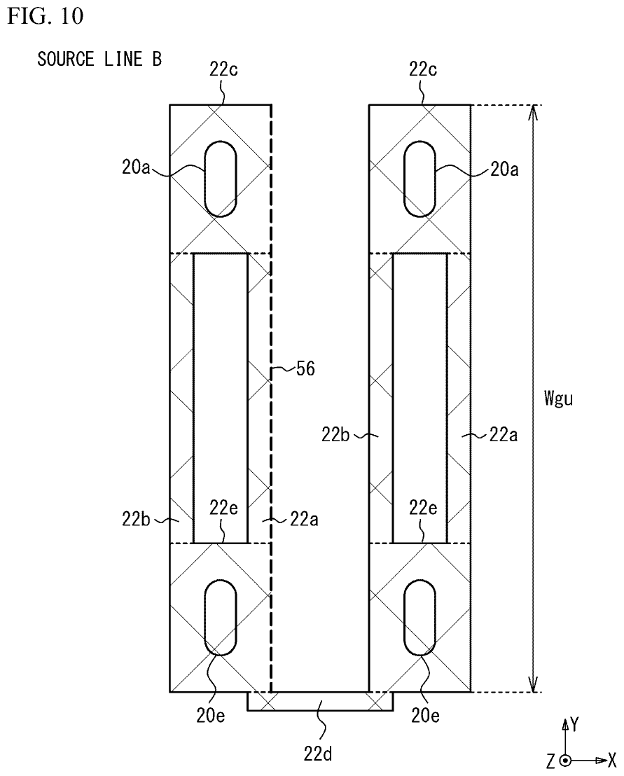

A source line B is the source line of first embodiment. FIG. 10 is a plan view of source line B in the simulation. As illustrated in FIG. 10, source line B is provided with source lines 22c and 22e arranged in the Y direction, and source lines 22a and 22b are electrically connected to source lines 22c and 22e. The other configuration of source line B is the same as that of source line A.

A width Wgu in the Y direction of source lines A and B is defined as a unit gate width. The inductance between via hole 20 (or 20a and 20e) and a + end side 56 of source line 22a in the X direction is defined as a source inductance Ls.

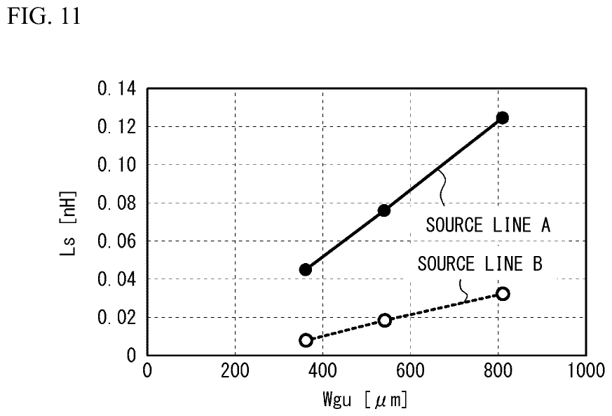

FIG. 11 is a diagram illustrating source inductance Ls with respect to a unit gate width Wgu in the simulation. As illustrated in FIG. 11, in source line A of the second comparative example, when unit gate width Wgu is increased, source inductance Ls is rapidly increased. On the other hand, in source line B of first embodiment, even if unit gate width Wgu is increased, the increase in source inductance Ls is gradual. As described above, in the first embodiment, the source inductance can be reduced as compared with the second comparative example.

According to the first embodiment, source electrode 12c and gate line 24 are disposed in source electrodes 12a and 12e when viewed in the Y direction. Gate lines 25a and 25c electrically connect gate line 24 to gate electrodes 14a and 14c. Thus, the gate resistance can be reduced as compared with the first comparative example without substantially increasing the size of the semiconductor device according to the first comparative example. In addition, transistor 35c is disposed between transistors 35a and 35e. The source potential is supplied to source electrodes 12a and 12e of transistors 35a and 35e via via holes 20a and 20e. Thus, the source inductance can be reduced as compared with the second comparative example without substantially increasing the size of the semiconductor device according to the second comparative example. Thus, deterioration of the high frequency characteristics can be reduced. Although the gate resistance is larger in the first embodiment than in the second comparative example, the high-frequency characteristics can be improved in the first embodiment than in the first and the second comparative examples by designing the semiconductor device so as to balance the gate resistance and the source inductance.

Gate bus bar 34 is electrically connected to gate electrode 14e. Thus, the gate potential can be supplied to gate line 24 via gate electrode 14e and gate line 25c. Thus, the gate resistance can be reduced.

Transistor 35b sharing source electrode 12a with transistor 35a and transistor 35f sharing source electrode 12e with transistor 35e are disposed. Source electrode 12c of transistor 35c, source electrode 12d of transistor 35d are disposed in source electrodes 12a and 12e when viewed in the Y direction. This enables miniaturization.

The number of each of transistors 35c and 35d in the Y direction may be one or more. As in the simulation, the source inductance can be reduced even if there are two transistors 35c and two transistors 35d in the Y direction. From the viewpoint of reducing the gate resistance, the number of each of transistors 35c and 35d in the Y direction may be plural. From the viewpoint of reducing the source inductance, the number of each of transistors 35c and 35d in the Y direction can be set to five or less, four or less, or three or less.

### Modification 1 of First Embodiment

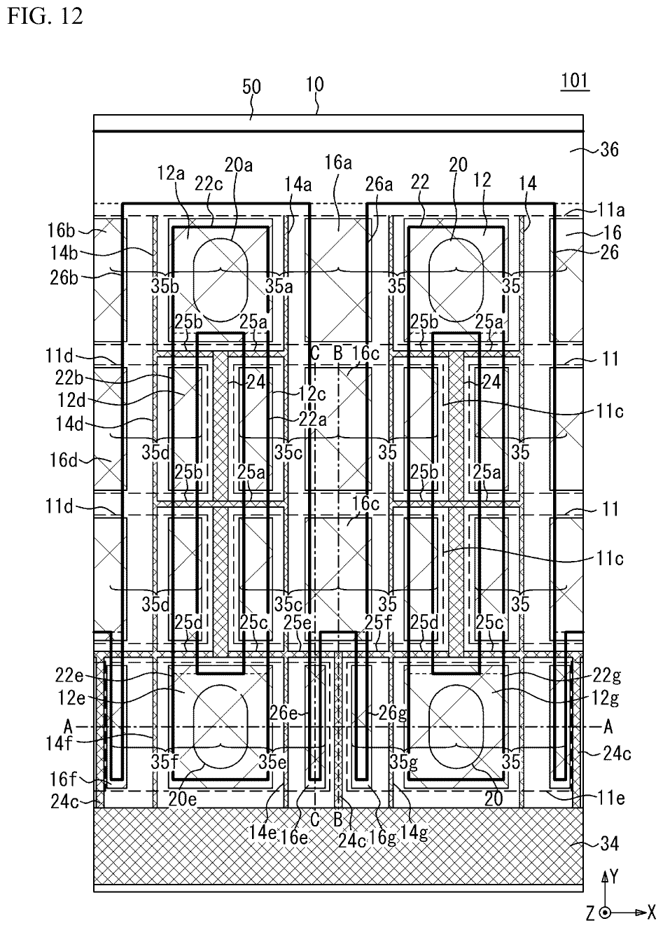

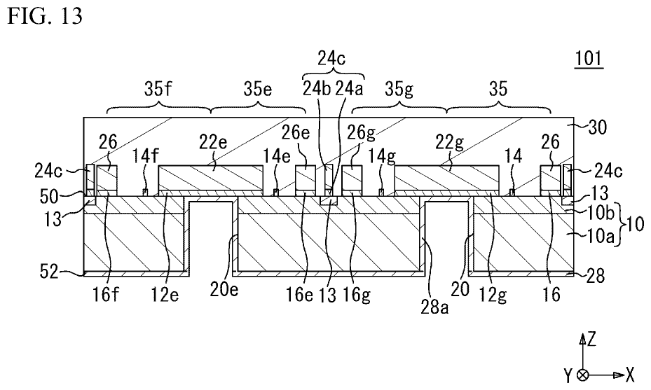

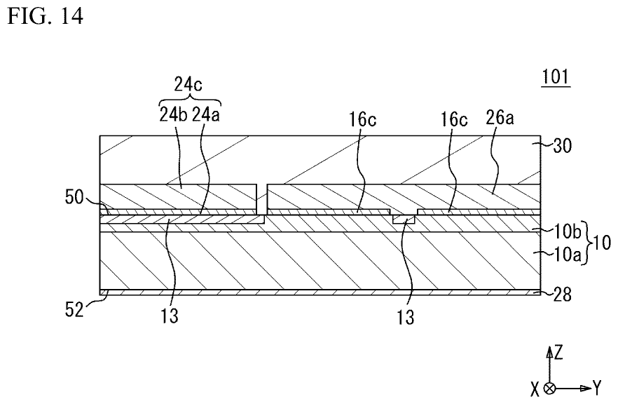

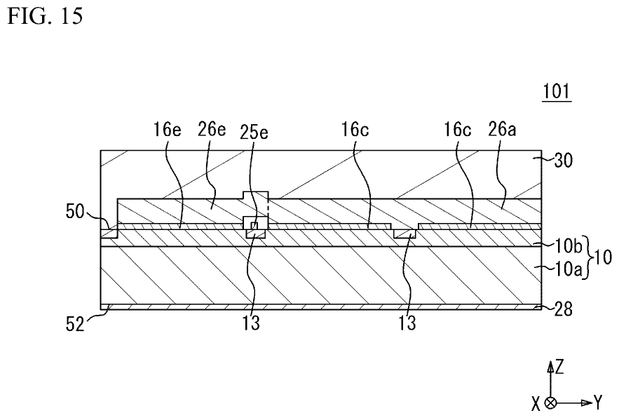

FIG. 12 is a plan view of a semiconductor device in a first modification 1 of the first embodiment. FIGS. 13 to 15 are an A-A cross-sectional view, a B-B cross-sectional view and a C-C cross-sectional view, respectively, of FIG. 12.

As illustrated in FIGS. 12 to 15, in a semiconductor device 101 of the first modification of the first embodiment, a transistor 35g is disposed in a region of the + direction in the X direction from transistor 35e.

Drain electrode 16e (second drain electrode) of transistor 35e (second transistor) is disposed in drain electrode 16a (first drain electrode) and drain electrode 16c (third drain electrode) when viewed in the Y direction. That is, drain electrode 16e is not disposed outside drain electrodes 16a or 16c when viewed in the Y direction.

Transistor 35g (seventh transistor) includes a source electrode 12g (fifth source electrode), a gate electrode 14g (seventh gate electrode), and a drain electrode 16g (seventh drain electrode). Gate electrode 14g is interposed between source electrode 12g and drain electrode 16g in the X direction. Drain electrode 16g is disposed in drain electrodes 16a and 16c when viewed in the Y direction. That is, drain electrode 16g is not disposed outside drain electrodes 16a or 16c when viewed in the Y direction. Source electrode 12g, gate electrode 14g, and drain electrode 16g are arranged in order in the − direction of the X direction.

A drain line 26e (first drain line) is disposed on and in contact with drain electrode 16e. Drain line 26e extends in the Y direction and electrically connects drain electrode 16e to drain electrodes 16a and 16c via drain line 26a. A drain line 26g (second drain line) is disposed on and in contact with drain electrode 16g. Drain line 26g extends in the Y direction and electrically connects drain electrode 16g to drain electrodes 16a and 16c via drain line 26a.

A gate line 24c (second gate line) extending in the Y direction is disposed on inactive region 13 between transistors 35e and 35g. Gate line 24c is disposed in drain electrodes 16a and 16c when viewed in the Y direction. That is, gate line 24c is not disposed outside drain electrodes 16a and 16c when viewed in the Y direction. Gate line 24c is electrically connected to gate bus bar 34. Gate line 24c includes gate metal layer 24a disposed on substrate 10 and wiring layer 24b disposed on and in contact with gate metal layer 24a.

A gate line 25e (third gate line) extending in the X direction is disposed on inactive region 13 between transistors 35c and 35e. Gate line 25e intersects drain line 26e without being in contact with drain line 26e, and electrically connects gate line 24c and gate line 25c. A gate line 25f extending in the X direction is disposed on inactive region 13 between drain electrodes 16c and 16g. Gate line 25f intersects drain line 26g without being in contact with drain line 26g, and electrically connects gate line 24c and gate electrode 14g. Other configurations of the first modification are the same as those of first embodiment, and the description thereof is omitted.

In the first modification of the first embodiment, gate line 24c (second gate line) is disposed in drain electrodes 16a and 16c when viewed in the Y direction, and is electrically connected to gate bus bar 34. Drain electrode 16e is interposed between gate line 24c and gate electrode 14e. Gate line 25e (third gate line) electrically connects gate line 24c to gate line 24 between transistors 35c and 35e. Thus, the gate potential is supplied to gate line 24 via gate lines 24c, 25e, and 25c. Thus, the gate resistance can be reduced as compared with the first embodiment.

Gate line 25f intersects drain line 26e without being in contact with drain line 26g, and electrically connects gate lines 24c and 24. Thus, the gate potential can be supplied to gate line 24 via gate lines 24c and 25c to 25e. A width of gate line 24c in the X direction and a width of each of gate lines 25e and 25f in the Y direction are larger than a width of each of gate electrodes 14e and 14g in the X direction and, for example, are twice or more the width of each of gate electrodes 14e and 14f in the X direction. This allows the gate resistance to be further reduced.

Drain electrode 16e of transistor 35e (second transistor), drain electrode 16g of transistor 35g (seventh transistor), and gate line 24c are disposed in drain electrodes 16a and 16c when viewed in the Y direction. This enables miniaturization.

### Second Modification of First Embodiment

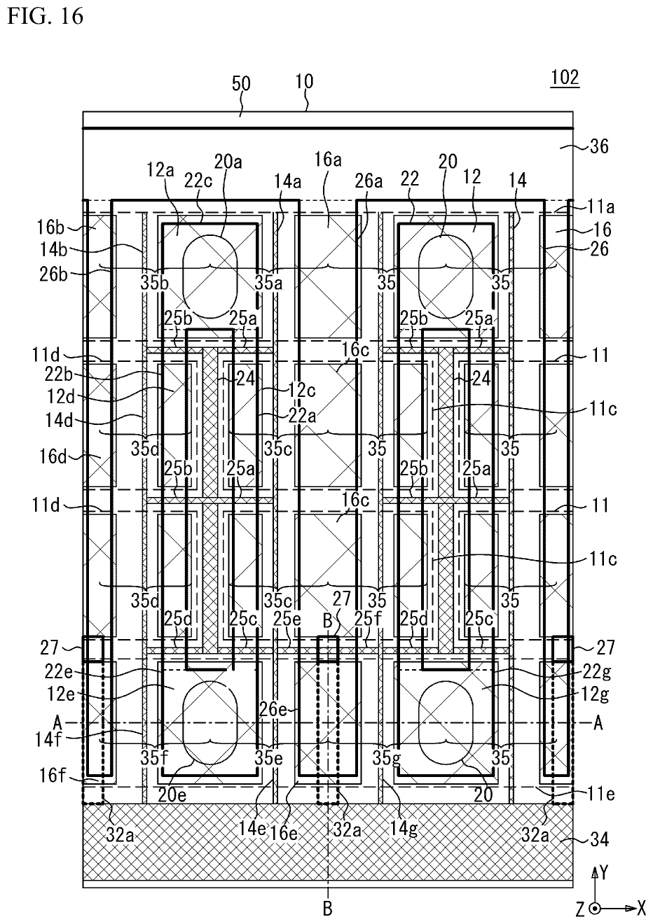

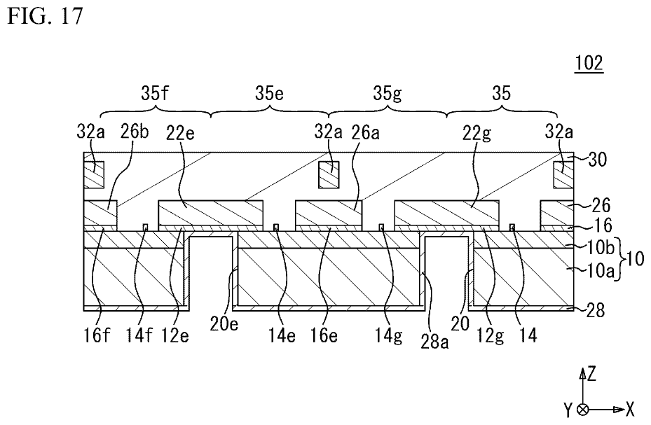

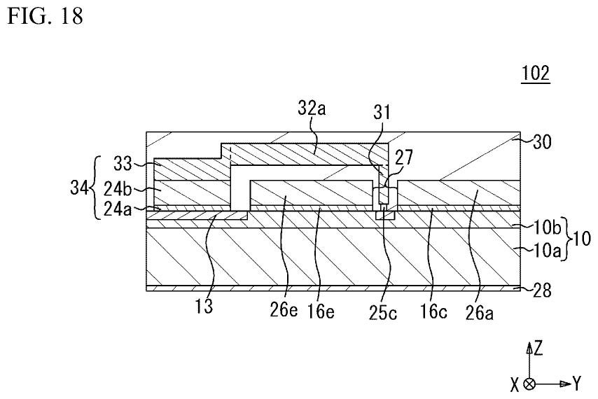

FIG. 16 is a plan view of a semiconductor device according to a second modification of the first embodiment. FIGS. 17 and 18 are an A-A cross-sectional view and a B-B cross-sectional view, respectively, of FIG. 16.

As illustrated in FIGS. 16 to 18, in a semiconductor device 102 of the second modification of the first embodiment, transistor 35g is disposed in a region of the + direction in the X direction from transistor 35e. Transistor 35g includes source electrode 12g, gate electrode 14g, and drain electrode 16e. Gate electrode 14g is interposed between source electrode 12g and drain electrode 16e in the X direction. Source electrode 12g, gate electrode 14g, and drain electrode 16e are arranged in order in the − direction of the X direction.

A gate line 32a is disposed above drain line 26a without being in contact with drain line 26a. Drain line 26a is disposed on drain electrode 16e. Gate line 32a is electrically connected to gate bus bar 34. Gate bus bar 34 is formed by sequentially disposing gate metal layer 24a, wiring layer 24b, and a wiring layer 33 on substrate 10.

Gate lines 25e and 25f extending in the X direction are disposed on inactive region 13 between drain electrodes 16c and 16e. Gate line 32a is electrically connected to gate lines 25e and 25f via a line 31 in an opening 27 extending through drain line 26a. Gate line 25e intersects drain line 26a without being in contact with drain line 26a, and electrically connects gate line 32a to gate line 25c. Gate line 25f intersects drain line 26a without being in contact with drain line 26a, and electrically connects gate line 32a to gate electrode 14g. Other configurations of the second modification are the same as those of first embodiment, and the description thereof is omitted.

According to the second modification of the first embodiment, gate line 32a (second gate line) overlaps drain electrode 16e without being in contact with drain electrode 16e when viewed in the Z direction, and is electrically connected to gate bus bar 34. Gate line 25e (third gate line) electrically connects gate line 24 to gate line 32a between transistors 35c and 35e. Thus, the gate potential is supplied to gate line 24 via gate line 32a, line 31, gate lines 25e, and 25c. Thus, the gate resistance can be reduced as compared with the first embodiment. A width of gate line 32a in the X direction is larger than a width of each of gate electrodes 14e and 14g in the X direction and, for example, is twice or more the width of each of gate electrodes 14e and 14f in the X direction. This allows the gate resistance to be further reduced.

### Third Modification of First Embodiment

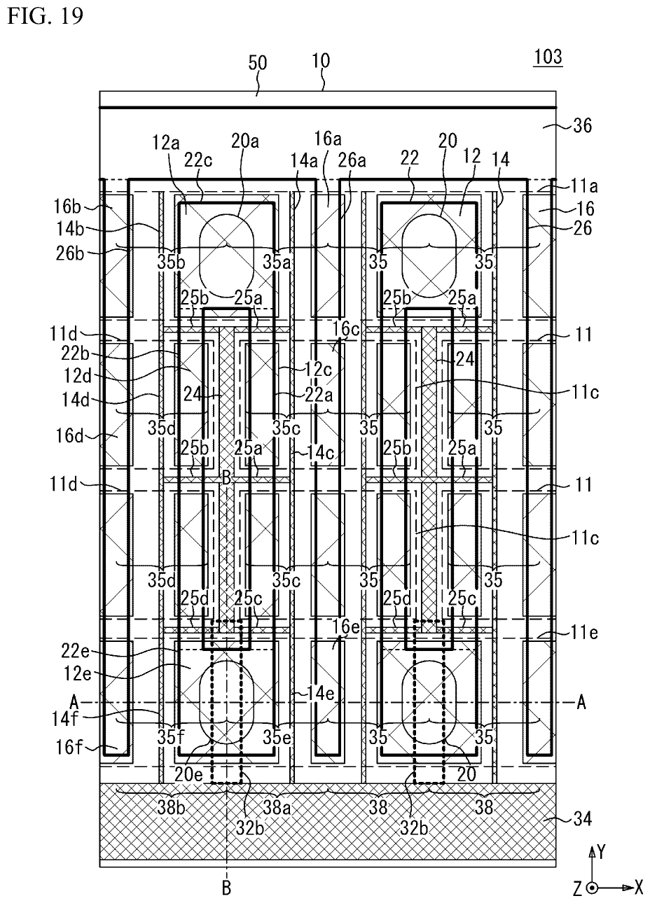

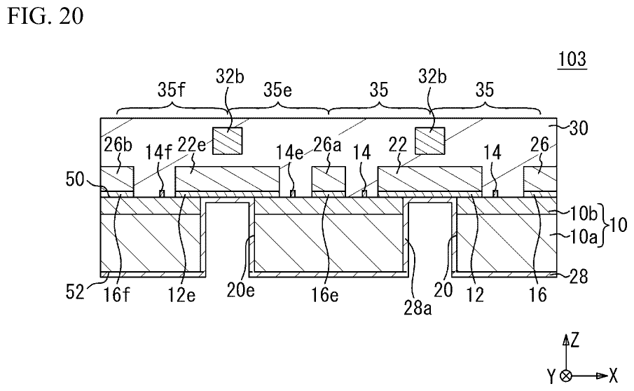

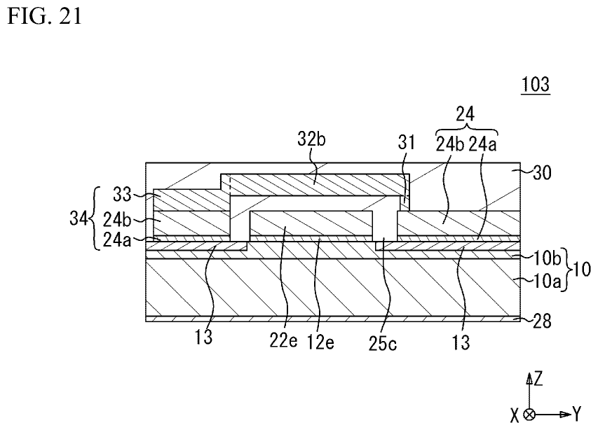

FIG. 19 is a plan view of a semiconductor device according to a third modification of the first embodiment. FIGS. 20 and 21 are an A-A cross-sectional view and a B-B cross-sectional view, respectively, of FIG. 19.

As illustrated in FIG. 19 to FIG. 21, in a semiconductor device 103 of the third modification of first embodiment, a gate line 32b is disposed above source line 22e without being in contact therewith. Gate line 32b is electrically connected to gate bus bar 34. Gate bus bar 34 is formed by sequentially disposing gate metal layer 24a, wiring layer 24b, and wiring layer 33 on substrate 10.

At the + end of gate line 32b in the Y direction, gate line 32b is electrically connected to gate line 24 via line 31. Other configurations of the third modification are the same as those of first embodiment, and the description thereof is omitted.

According to the third modification of the first embodiment, gate line 32b (second gate line) overlaps source electrode 12e without being in contact with source electrode 12e when viewed in the Z direction, and electrically connects gate bus bar 34 to gate line 24. Thus, the gate potential is supplied to gate line 24 via gate line 32b and line 31. Thus, the gate resistance can be reduced as compared with the first embodiment. A width of gate line 32b in the X direction is larger than a width of each of gate electrodes 14e and 14f in the X direction and, for example, are twice or more the width of each of gate electrodes 14e and 14f in the X direction. This allows the gate resistance to be further reduced.

The first to the third modifications of the first embodiment can reduce the gate resistance as compared with the first embodiment. In the first modification of the first embodiment, drain line 26e and gate line 25e overlap each other when viewed in the Z direction, and thus the gate-drain parasitic capacitance is larger than that in the first embodiment. In the second modification of the first embodiment, drain line 26a and gate line 32a overlap each other when viewed in the Z direction, and thus the gate-drain parasitic capacitance is larger than that in the first embodiment. The first modification of the first embodiment can reduce the gate-drain parasitic capacitance more than the second modification of the first embodiment. In the third modification of the first embodiment, source line 22e and gate line 32b overlap each other when viewed in the Z direction, and thus the gate-source parasitic capacitance is larger than that in the first embodiment. A semiconductor device to be used from the semiconductor devices of the first embodiment and the first to the third modifications thereof is may be determined in consideration of the balance among the gate resistance, the source inductance, the gate-drain parasitic capacitance, and the gate-source parasitic capacitance in order to improve the high-frequency characteristics.

### Fourth Modification of First Embodiment

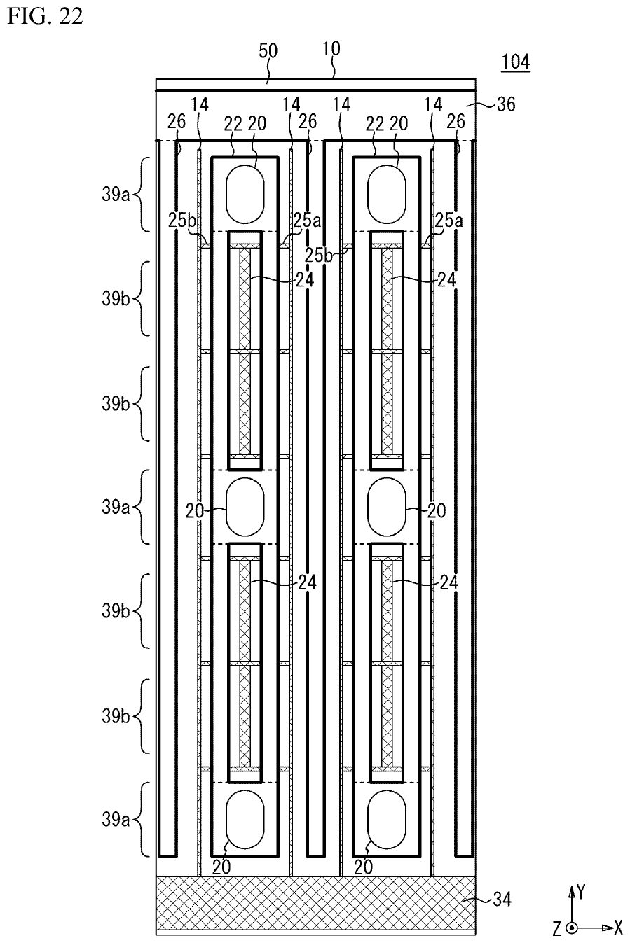

FIG. 22 is a simplified plan view of a semiconductor device according to a fourth modification of the first embodiment. In FIG. 22, active regions 11, source electrodes 12, and drain electrodes 16 are not illustrated. As illustrated in FIG. 22, in a semiconductor device 104 of the fourth modification of the first embodiment, of transistor groups 39a and 39b arranged in the Y direction, a transistor group closest to drain bus bar 36 is transistor group 39a, and a transistor group closest to gate bus bar 34 is transistor group 39a. Transistor groups 39a and 39b are disposed seven in total, and two transistor groups 39b are disposed between transistor groups 39a adjacent to each other in the Y direction. The other configurations of the fourth modification are the same as those of FIG. 6 of the first embodiment, and the description thereof is omitted.

### Modification 5 of First Embodiment

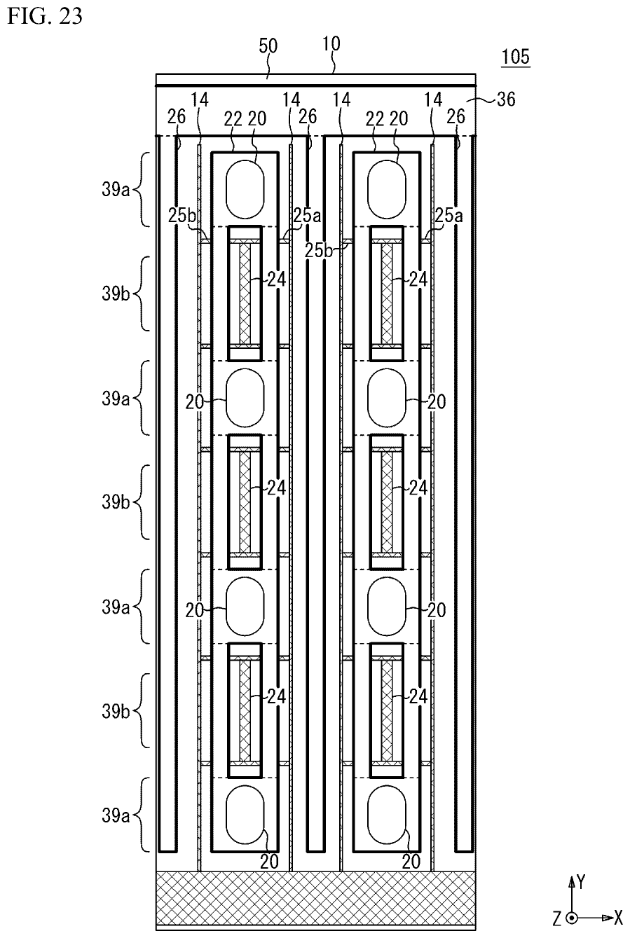

FIG. 23 is a simplified plan view of a semiconductor device according to a fifth modification of the first embodiment. In FIG. 23, active regions 11, source electrodes 12, and drain electrodes 16 are not illustrated. As illustrated in FIG. 23, in a semiconductor device 105 of the fifth modification of the first embodiment, one transistor group 39b is disposed between transistor groups 39a adjacent in the Y direction. The other configurations of the fifth embodiment are the same as those of the fourth modification of the first embodiment, and the description thereof will be omitted.

As in the fourth and the fifth modifications of the first embodiment, at least two transistor groups 39a may be disposed in the Y direction, and at least one transistor group 39b may be disposed between adjacent transistor groups 39a in the Y direction.

In the first embodiment and the modifications thereof, the example in which four transistor groups 39a and 39b are arranged in the Y direction has been described, but five or more transistor groups 39a and 39b may be arranged in the Y direction. The source lines sandwiching drain line 26 in the X direction may be connected between drain line 26 and gate bus bar 34.

In first embodiment and the modifications thereof, the plurality of drain electrodes 16 (for example, drain electrodes 16a, 16c, and 16e) electrically connected to the same drain line 26 (for example, drain line 26a) are separated from each other in inactive region 13. The plurality of drain electrodes 16 (for example, drain electrodes 16a, 16c, and 16e) electrically connected to drain line 26 (for example, drain line 26a) may be connected to each other in inactive region 13. In transistor 35 (for example, transistor 35a), source electrode 12 and source line 22 (for example, source electrode 12a and source line 22c) may be collectively referred to as a source electrode, and drain electrode 16 and drain line 26 (for example, drain electrode 16a and drain line 26a) may be collectively referred to as a drain electrode.

### Second Embodiment

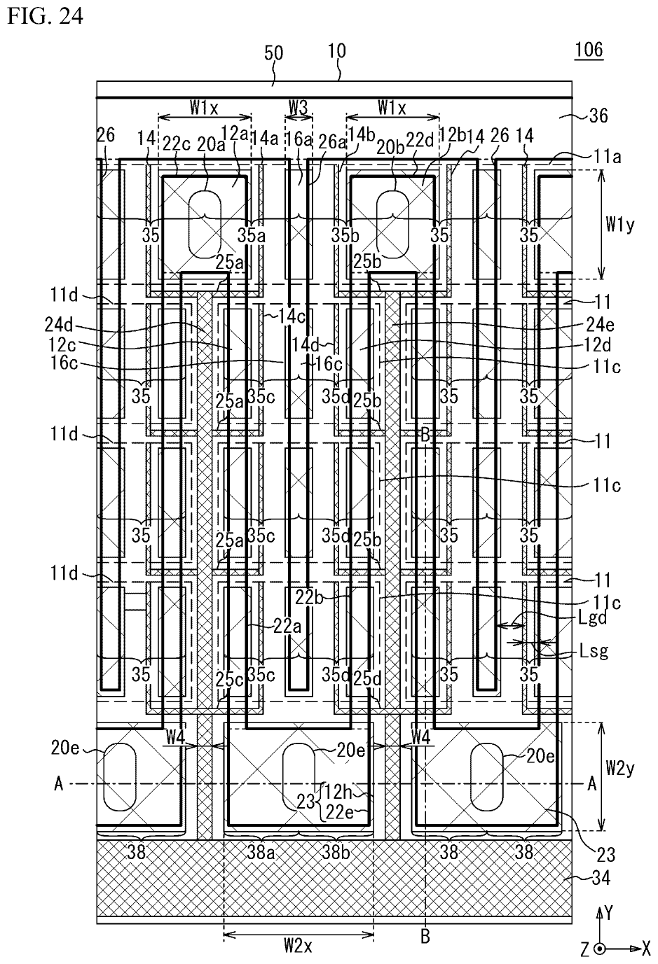

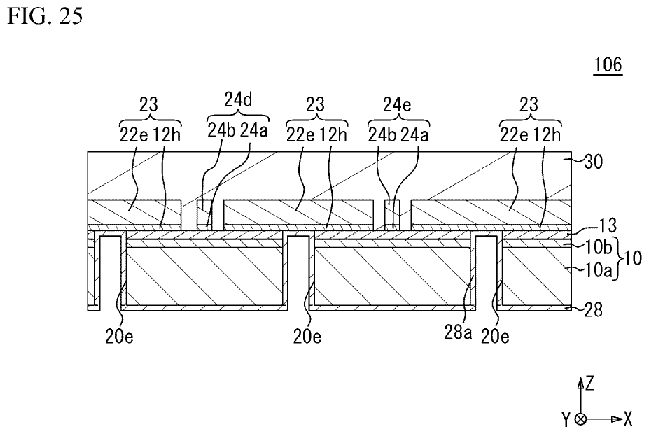

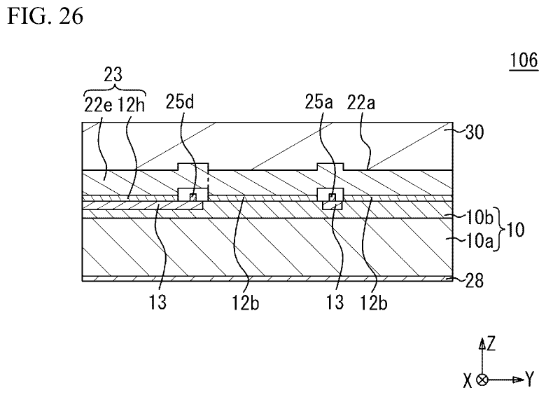

FIG. 24 is a plan view of a semiconductor device according to a second embodiment. FIGS. 25 and 26 are an A-A cross-sectional view and a B-B cross-sectional view, respectively, of FIG. 24.

As illustrated in FIGS. 24 to 26, in a semiconductor device 106 of the second embodiment, a plurality of transistors 35 and 35a to 35d are disposed on the main surface of substrate 10. Transistors 35, 35a to 35d arranged in the Y direction form transistor groups 38, 38a and 38b.

Transistors 35 closest to drain bus bar 36 are transistors 35a and 35b. Transistors 35 closer to gate bus bar 34 than transistors 35a and 35b are transistors 35c and 35d. Transistor group 38a includes one transistor 35a and three transistors 35c. Transistor group 38b includes one transistor 35b and three transistors 35d. The number of transistor 35c is one or more, and the number of transistor 35d is one or more.

Active region 11a extends in the X direction. Active regions 11c and 11d are arranged in the X direction. Transistors 35a and 35b are disposed in active region 11a. Transistors 35c and 35d are disposed in active region 11c.

Transistor 35a (first transistor) includes source electrode 12a (first source electrode), gate electrode 14a (first gate electrode), and drain electrode 16a (first drain electrode). Gate electrode 14a is interposed between source electrode 12a and drain electrode 16a in the X direction. Source electrode 12a, gate electrode 14a, and drain electrode 16a are arranged in order in the + direction of the X direction.

Transistor 35c (second transistor) includes source electrode 12c (second source electrode), gate electrode 14c (second gate electrode), and drain electrode 16c (second drain electrode). Gate electrode 14c is interposed between source electrode 12c and drain electrode 16c in the X direction. Source electrode 12c is disposed in source electrode 12a when viewed in the Y direction. That is, source electrode 12c is not disposed outside source electrode 12a when viewed in the Y direction. The plurality of drain electrodes 16c overlap drain electrode 16a when viewed in the Y direction. Source electrode 12c, gate electrode 14c, and drain electrode 16c are arranged in order in the + direction of the X direction.

Transistor 35b (third transistor) includes a source electrode 12b (third source electrode), gate electrode 14b (third gate electrode), and drain electrode 16a (first drain electrode). Drain electrode 16a is shared by transistors 35a and 35b. Drain electrode 16a is interposed between source electrode 12b and gate electrode 14a. Gate electrode 14b is interposed between source electrode 12b and drain electrode 16a in the X direction. Source electrode 12b, gate electrode 14b, and drain electrode 16a are arranged in order in the − direction of the X direction.

Transistor 35d (fourth transistor) includes source electrode 12d (fourth source electrode), gate electrode 14d (fourth gate electrode), and drain electrode 16c (second drain electrode). Drain electrode 16c is shared by transistors 35c and 35d. Drain electrode 16c is interposed between source electrode 12d and gate electrode 14c. Gate electrode 14d is interposed between source electrode 12d and drain electrode 16c in the X direction. Source electrode 12d is disposed in source electrode 12b when viewed in the Y direction. That is, source electrode 12d is not disposed outside source electrode 12b when viewed in the Y direction. Source electrode 12d, gate electrode 14d, and drain electrode 16c are arranged in order in the − direction of the X direction.

A source connection line 23 is disposed on inactive region 13 of main surface 50 between transistor groups 38, 38a, and 38b and gate bus bar 34. Source connection line 23 includes an ohmic electrode layer 12h and source line 22e disposed on and in contact with ohmic electrode layer 12h. Source connection line 23 electrically connects source lines 22a and 22b to each other.

Source line 22c is disposed on and in contact with source electrode 12a. Source line 22d is disposed on and in contact with source electrode 12b. Source line 22a (first source line) is disposed on and in contact with source electrode 12c. Source line 22a extends in the Y direction, electrically connects the plurality of source electrodes 12c to each other, and electrically connects the plurality of source electrodes 12c to source line 22c and source connection line 23. Source line 22b (second source line) is disposed on and in contact with source electrode 12d. Source line 22b extends in the Y direction, electrically connects the plurality of source electrodes 12d to each other, and electrically connects the plurality of source electrodes 12d to source line 22d and source connection line 23.

Drain line 26a is disposed on and in contact with drain electrodes 16a and 16c. Drain line 26a extends in the Y direction, electrically connects the plurality of drain electrodes 16a and 16c to each other, and electrically connects the plurality of drain electrodes 16a and 16c to drain bus bar 36.

Gate lines 24d (first gate line) and 24e (second gate line) extending in the Y direction are disposed on two inactive regions 13 sandwiching transistors 35c and 35d, respectively. Gate line 24d is disposed in source electrode 12a when viewed in the Y direction. That is, gate line 24d is not disposed outside source electrode 12a when viewed in the Y direction. Gate line 24e is disposed in source electrode 12b when viewed in the Y direction. That is, gate line 24e is not disposed outside source electrode 12b when viewed in the Y direction. Gate lines 24d and 24e are electrically connected to gate bus bar 34. Gate lines 24d and 24e include gate metal layer 24a disposed on substrate 10 and wiring layer 24b disposed on and in contact with gate metal layer 24a.

Gate line 25a extending in the X direction is disposed on inactive region 13 between transistors 35a and 35c and between transistors 35c. Gate line 25a intersects source line 22a without being in contact with source line 22a, and electrically connects gate line 24d to gate electrodes 14a and 14c.

Gate line 25b extending in the X direction is disposed on inactive region 13 between transistors 35b and 35d and between transistors 35d. Gate line 25b intersects source line 22b without being in contact with source line 22b, and electrically connects gate line 24e to gate electrodes 14b and 14d.

Gate line 25c extending in the X direction is disposed on inactive region 13 between transistor 35c and source connection line 23. Gate line 25c intersects source line 22a without being in contact with source line 22a, and electrically connects gate line 24d to gate electrode 14c.

Gate line 25d extending in the X direction is disposed on inactive region 13 between transistor 35d and source connection line 23. Gate line 25d intersects source line 22b without being in contact with source line 22b, and electrically connects gate line 24e to gate electrode 14d.

Via holes 20a, 20b, and 20e extend through substrate 10. Via holes 20a, 20b, and 20e overlap source electrodes 12a and 12b and source connection line 23, respectively, when viewed in the Z direction, and are electrically connected to source electrodes 12a and 12b and source connection line 23, respectively. Metal layer 28 is disposed on back surface 52 of substrate 10. Metal layer 28a is disposed on inner surfaces of via holes 20a, 20b, and 20e. Thus, metal layer 28 (back-surface metal layer) is electrically connected to source electrodes 12a and 12b and source connection line 23 via via holes 20a (first via hole), 20b (second via hole), and 20e (third via hole), respectively. Via hole 20 is not connected to source electrodes 12c or 12d. A planar shape of via holes 20a, 20b, and 20e may be an ellipse, an oval, a rounded rectangle, or a circle.

A source potential (for example, a reference potential such as a ground potential) is supplied from metal layer 28 to source electrodes 12a and 12b and source connection line 23 via metal layer 28a in via holes 20a, 20b, and 20e. Further, the source potential is supplied from source line 22c, the 22d, and source connection line 23 to source electrodes 12c and 12d via source lines 22a and 22b, respectively. A gate potential (for example, a high-frequency signal and a gate bias voltage) is supplied from gate bus bar 34 to gate electrodes 14a to 14d via gate lines 24d, 24e, and 25a to 25d. A drain bias voltage is supplied from drain bus bar 36 to drain electrodes 16a and 16c via drain line 26a. The high-frequency signal amplified by each of transistors 35a to 35d is output from drain line 26a to drain bus bar 36.

The + ends of gate electrodes 14c and 14d in the Y direction are not connected to the − ends of gate electrodes 14a or 14b in the Y direction. The + ends of gate electrodes 14c and 14d in the Y direction may be connected to the − ends of gate electrodes 14a and 14b in the Y direction. The other configurations are the same as those of the first embodiment, and the description thereof is omitted.

According to the second embodiment, source connection line 23 is located with transistors 35c and 35d interposed between transistors 35a, 35d and source connection line 23, and electrically connects source electrode 12c to source electrode 12d. Metal layer 28 (back-surface metal layer) is electrically connected to source electrodes 12a and 12b and source connection line 23 via via holes 20a, 20b, and 20e, and is short-circuited. Thus, the gate resistance can be reduced as compared with the first comparative example. The source inductance can be reduced as compared with the second comparative example. Thus, deterioration of the high frequency characteristics can be reduced.

Source connection line 23 is disposed in inactive region 13 where substrate 10 is inactivated. This allows the parasitic capacitance to be reduced.

In the X direction, source connection line 23 is interposed between gate lines 24d and 24e. Thus, the gate potential can be supplied to gate lines 24d and 24e from the − direction in the Y direction.

Gate bus bar 34 is located with source connection line 23 interposed between gate bus bar 34 and a transistor group including transistors 35c and 35d, and is electrically connected to gate lines 24d and 24e. Thus, the gate potential can be supplied from gate bus bar 34 to gate electrodes 14a to 14d via gate lines 24d and 24e.

A width W2x of source connection line 23 in the X direction is larger than a width W1x of each of source electrodes 12a and 12b in the X direction. This is because a larger current flows through drain line 26a than through gate lines 24d and 24e. Thus, a width W3 of drain line 26a in the X direction is made larger than a width W4 of gate lines 24d and 24e in the X direction. In addition, in a transistor used for a power amplifier, a distance Lgd between the gate electrode and the drain electrode is made larger than the distance Lsg between the source electrode and the gate electrode. The width W2x is, for example, 1.1 times or more, 1.2 times or more, and 10 times or less than the width W1x. The width W3 is, for example, 1.2 times or more, 1.5 times or more, and 10 times or less than the width W4. The distance Lgd is, for example, 1.2 times or more, 1.5 times or more, and 10 times or less than the distance Lsg. The width W2x may be equal to the width W1x or smaller than the width W1x.

The number of each of transistors 35c and 35d in the Y direction may be one or more. From the viewpoint of reducing the gate resistance, the number of each of transistors 35c and 35d in the Y direction may be plural. From the viewpoint of reducing the source inductance, the number of each of transistors 35c and 35d in the Y direction can be set to five or less, four or less, or three or less.

### First Modification 1 of Second Embodiment

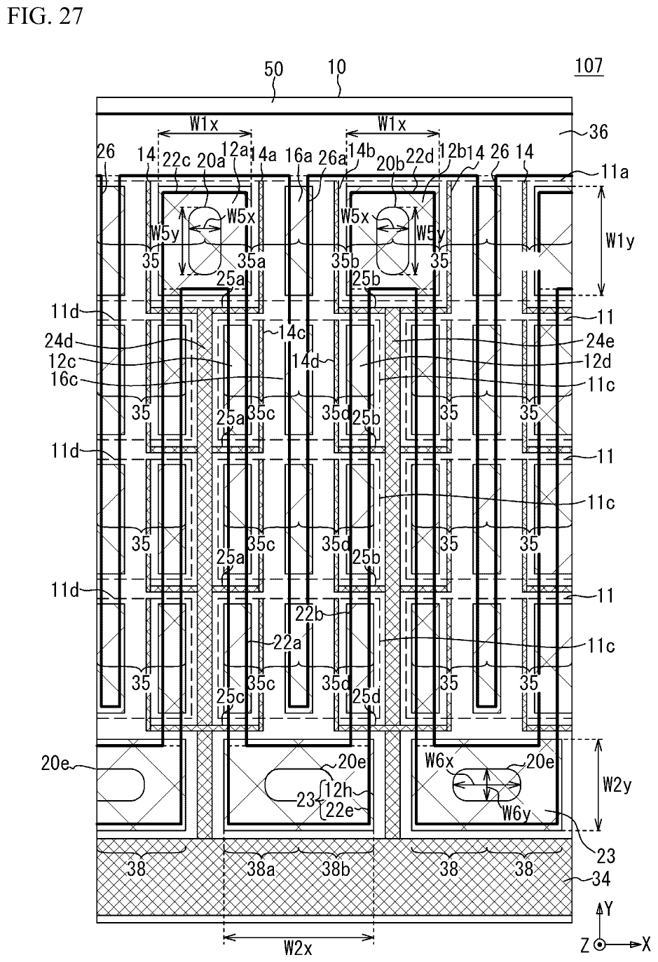

FIG. 27 is a plan view of a semiconductor device according to a first modification of a second embodiment. As illustrated in FIG. 27, in a semiconductor device 107 of the first modification of the second embodiment, a width W2x of source connection line 23 in the X direction is larger than a width W1x of source electrodes 12a and 12b in the X direction. Furthermore, a width W2y of source connection line 23 in the Y direction is smaller than a width Wly of source electrodes 12a and 12b in the Y direction. A width W5x of via holes 20a and 20b in the X direction is smaller than a width W5y in the Y direction. A width W6x of via hole 20e in the X direction is larger than a width W6y in the Y direction. Other configurations of the first modification of the second embodiment are the same as those of the second embodiment, and the description thereof is omitted.

The planar shape of via holes 20a, 20b, and 20e may be a shape having a major axis and a minor axis, such as an ellipse, an oval, or a rounded rectangle. In source electrodes 12a and 12b, for example, the width W1y is larger than the width W1x. Thus, the major axis direction of via holes 20a and 20b is defined as the Y direction. This makes it possible to increase via holes 20a and 20b and reduce the source inductance.

Due to the restriction of etching when via holes 20a, 20b, and 20e are formed in substrate 10, the planar shapes and areas of via holes 20a, 20b, and 20e may be set to be the same as the manufacturing error. As in the second embodiment, when the major axis direction of via hole 20e is set to the Y direction, the width W2y of source connection line 23 in the Y direction is increased. Thus, the major axis direction of via hole 20e is set as the X direction. This makes it possible to reduce the width W2y of source connection line 23 in the Y direction, and to reduce the size of semiconductor device 107.

The major axis direction of via holes 20a and 20b may not be the Y direction, as long as the width W5x in the X direction is smaller than the width W5y in the Y direction. The major axis direction of via hole 20e may not be the X direction, as long as the width W6x of via hole 20e in the X direction is larger than the width W6y in the Y direction.

The width W2y is, for example, 0.9 times or less, 0.7 times or less, and 0.1 times or more of the width W2x. The widths W5y and W6x are, for example, 1.2 times or more, 1.5 times or more, or 2 times or more of the widths W5x and Woy.

### Second Modification of Second Embodiment

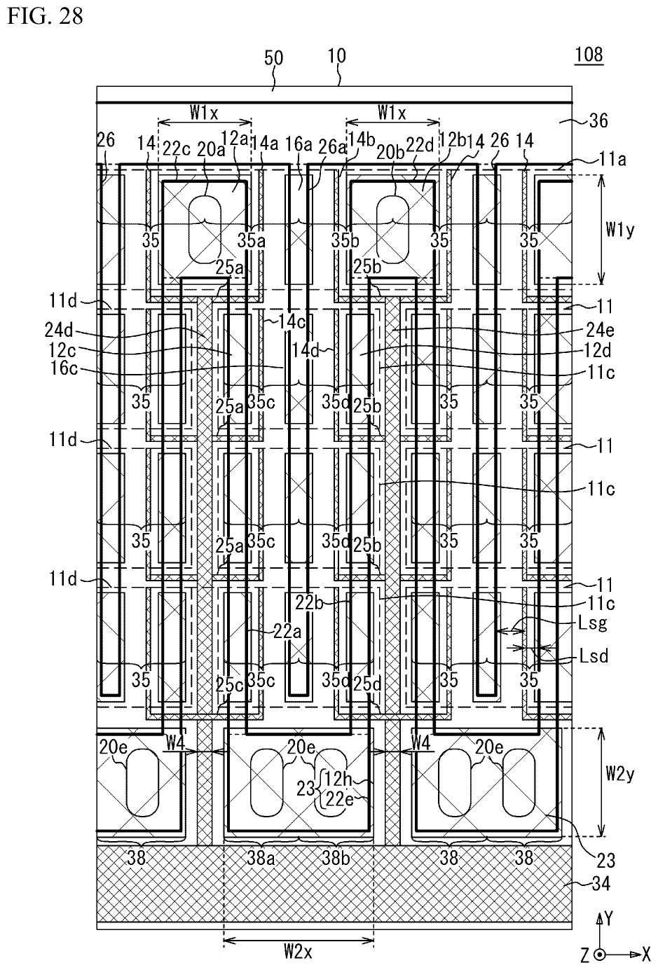

FIG. 28 is a plan view of a semiconductor device according to a second modification of the second embodiment. As illustrated in FIG. 28, in a semiconductor device 108 of the second modification of the second embodiment, one via hole 20a is provided for one source electrode 12a, and one via hole 20b is provided for one source electrode 12b. On the other hand, two via holes 20e are provided for one source connection line 23. Other configurations of the second modification of the second embodiment are the same as those of the second embodiment, and the description thereof is omitted.

As in the second modification of the second embodiment, when the width W2x of source connection line 23 in the X direction is larger than the width W1x of source electrodes 12a and 12b in the X direction, the number N2 of via holes 20e connected to one source connection line 23 can be made larger than the number N1 of via holes 20a connected to one source electrode 12a and the number N1 of via holes 20b connected to one source electrode 12b. This allows the source inductance to be reduced. The number N2 is, for example, 2 or 3, or the number N1 is, for example, 1.

In the second embodiment and the modifications thereof, the example in which five transistor groups 38a and 38b are arranged in the X direction has been described, but six or more transistor groups 38a and 38b may be arranged in the X direction.

In the second embodiment and the modifications thereof, a plurality of drain electrodes 16 (for example, drain electrodes 16a and 16c) electrically connected to the same drain line 26 (for example, drain line 26a) are separated from each other in inactive region 13. The plurality of drain electrodes 16 (e.g., drain electrodes 16a and 16c) electrically connected to drain line 26 (e.g., drain line 26a) may be connected to each other in inactive region 13. In transistor 35 (for example, transistor 35a), source electrode 12 and source line 22 (for example, source electrode 12a and source line 22c) may be collectively referred to as a source electrode, and drain electrode 16 and drain line 26 (for example, drain electrode 16a and drain line 26a) may be collectively referred to as a drain electrode.

The embodiments disclosed herein are to be considered in all respects as illustrative and not restrictive. The scope of the present disclosure is defined by the appended claims rather than the foregoing description, and is intended to include all modifications within the scope and meaning equivalent to the claims.

1. A semiconductor device comprising:
a substrate having a main surface and a back surface opposite to the main surface;
a first transistor disposed on the main surface, the first transistor including a first source electrode, a first drain electrode, and a first gate electrode interposed between the first source electrode and the first drain electrode in a first direction;
a second transistor disposed on the main surface, the second transistor including a second source electrode, a second drain electrode, and a second gate electrode interposed between the second source electrode and the second drain electrode in the first direction, the second source electrode overlapping the first source electrode when viewed in a second direction intersecting the first direction, the second drain electrode being electrically connected to the first drain electrode;
a third transistor disposed on the main surface between the first transistor and the second transistor, the third transistor including a third source electrode, a third drain electrode, and a third gate electrode interposed between the third source electrode and the third drain electrode in the first direction, the third source electrode being disposed in the first source electrode and the second source electrode when viewed in the second direction, the third source electrode being electrically connected to the first source electrode and the second source electrode, the third drain electrode being electrically connected to the first drain electrode and the second drain electrode;
a first gate line disposed on the main surface and located with the third source electrode interposed between the first gate line and the third gate electrode, the first gate line being disposed in the first source electrode and the second source electrode when viewed in the second direction, the first gate line being electrically connected to the first gate electrode and the second gate electrode; and
a back-surface metal layer disposed on the back surface, the back-surface metal layer being electrically connected to the first source electrode and the second source electrode via a first via hole and a second via hole, respectively, the first via hole and the second via hole overlapping the first source electrode and the second source electrode when viewed in a thickness direction of the substrate, respectively.

2. The semiconductor device according to claim 1, comprising:
a gate bus bar located with the second transistor interposed between the gate bus bar and the third transistor, the gate bus bar being electrically connected to the second gate electrode;
a second gate line disposed on the main surface and located with the second drain electrode interposed between the second gate line and the second gate electrode, the second gate line being disposed in the first drain electrode and the third drain electrode when viewed in the second direction, the second gate line being electrically connected to the gate bus bar; and
a third gate line disposed on the main surface, the third gate line being located between the second transistor and the third transistor and electrically connecting the first gate line and the second gate line to each other,
wherein the second drain electrode is disposed in the first drain electrode and the third drain electrode when viewed in the second direction.

3. The semiconductor device according to claim 2, comprising:
a first drain line disposed on the main surface, the first drain line electrically connecting the second drain electrode and the third drain electrode to each other,
wherein the third gate line intersects the first drain line without being in contact with the first drain line and electrically connects the first gate line and the second gate line to each other.

4. The semiconductor device according to claim 1, comprising:
a gate bus bar located with the second transistor interposed between the gate bus bar and the third transistor, the gate bus bar being electrically connected to the second gate electrode;
a second gate line disposed on the main surface, the second gate line overlapping the second drain electrode without being in contact with the second drain electrode when viewed in the thickness direction of the substrate, the second gate line being electrically connected to the gate bus bar; and
a third gate line disposed on the main surface, the third gate line being located between the second transistor and the third transistor and electrically connecting the first gate line and the second gate line to each other.

5. The semiconductor device according to claim 1, comprising:
a gate bus bar located with the second transistor interposed between the gate bus bar and the third transistor, the gate bus bar being electrically connected to the second gate electrode; and
a second gate line disposed on the main surface, the second gate line overlapping the second source electrode without being in contact with the second source electrode when viewed in the thickness direction of the substrate, the second gate line electrically connecting the gate bus bar and the first gate line to each other.

6. The semiconductor device according to claim 1, wherein
the third transistor includes a plurality of third transistors arranged in the second direction.

7. The semiconductor device according to claim 1, comprising:
a fourth transistor disposed on the main surface, the fourth transistor including the first source electrode, a fourth drain electrode, and a fourth gate electrode interposed between the first source electrode and the fourth drain electrode in the first direction, the fourth drain electrode being located with the first source electrode between the fourth drain electrode and the first gate electrode, the fourth gate electrode being electrically connected to the first gate line;
a fifth transistor disposed on the main surface, the fifth transistor including the second source electrode, a fifth drain electrode, and a fifth gate electrode interposed between the second source electrode and the fifth drain electrode in the first direction, the fifth drain electrode being electrically connected to the fourth drain electrode and being located with the second source electrode interposed between the fifth drain electrode and the second gate electrode; and
a sixth transistor disposed on the main surface between the fourth transistor and the fifth transistor, the sixth transistor including a fourth source electrode, a sixth drain electrode, and a sixth gate electrode interposed between the fourth source electrode and the sixth drain electrode in the first direction, the fourth source electrode being disposed in the first source electrode and the second source electrode when viewed in the second direction, the fourth source electrode being electrically connected to the first source electrode and the second source electrode, the sixth drain electrode being electrically connected to the fourth drain electrode and the fifth drain electrode, the sixth gate electrode being electrically connected to the first gate line.

8. The semiconductor device according to claim 2, comprising:
a seventh transistor disposed on the main surface, the seventh transistor including a seventh drain electrode, a fifth source electrode, and a seventh gate electrode interposed between the fifth source electrode and the seventh drain electrode in the first direction, the seventh drain electrode being located with the second gate line interposed between the seventh drain electrode and the second drain electrode, the seventh drain electrode being disposed in the first drain electrode and the third drain electrode when viewed in the second direction, the seventh drain electrode being electrically connected to the first drain electrode and the third drain electrode, the fifth source electrode being located with the seventh drain electrode interposed between the fifth source electrode and the second gate line.

9. A semiconductor device comprising:
a substrate having a main surface and a back surface opposite to the main surface;
a first transistor disposed on the main surface, the first transistor including a first source electrode, a first drain electrode, and a first gate electrode interposed between the first source electrode and the first drain electrode in a first direction;
a second transistor disposed on the main surface, the second transistor including a second source electrode, a second drain electrode, and a second gate electrode interposed between the second source electrode and the second drain electrode in the first direction, the second source electrode being disposed in the first source electrode when viewed in a second direction intersecting the first direction, the second source electrode being electrically connected to the first source electrode, the second drain electrode being electrically connected to the first drain electrode;
a third transistor disposed on the main surface, the third transistor including a third source electrode, the first drain electrode, and a third gate electrode interposed between the third source electrode and the first drain electrode in the first direction, the third source electrode being located with the first drain electrode interposed between the third source electrode and the first gate electrode;
a fourth transistor disposed on the main surface, the fourth transistor including a fourth source electrode, the second drain electrode, and a fourth gate electrode interposed between the fourth source electrode and the second drain electrode in the first direction, the fourth source electrode being disposed in the third source electrode when viewed in the second direction, the fourth source electrode being electrically connected to the third source electrode;
a first gate line disposed on the main surface and located with the second source electrode interposed between the first gate line and the second gate electrode in the first direction, the first gate line being disposed in the first source electrode when viewed in the second direction, the first gate line being electrically connected to the first gate electrode;
a second gate line disposed on the main surface and located with the fourth source electrode interposed between the second gate line and the fourth gate electrode in the first direction, the second gate line being disposed in the third source electrode when viewed in the second direction, the second gate line being electrically connected to the third gate electrode;
a source connection line disposed on the main surface and located with the second transistor and the fourth transistor interposed between the source connection line and a transistor group including the first transistor and the third transistor, the source connection line electrically connecting the second source electrode and the fourth source electrode to each other; and
a back-surface metal layer disposed on the back surface, the back-surface metal layer being electrically connected to the first source electrode, the third source electrode, and the source connection line via a first via hole, a second via hole, and a third via hole, respectively, the first via hole, the second via hole, and the third via hole overlapping the first source electrode, the third source electrode, and the source connection line when viewed in a thickness direction of the substrate, respectively.

10. The semiconductor device according to claim 9, wherein the source connection line is disposed in an inactive region where the substrate is inactivated.

11. The semiconductor device according to claim 9, wherein the source connection line is interposed between the first gate line and the second gate line in the first direction.

12. The semiconductor device according to claim 11, comprising:
a gate bus bar located with the source connection line interposed between the gate bus bar and a transistor group including the second transistor and the fourth transistor, the gate bus bar being electrically connected to the first gate line and the second gate line.

13. The semiconductor device according to claim 9, wherein a width of the source connection line in the first direction is larger than a width of the first source electrode in the first direction and a width of the third source electrode in the first direction.

14. The semiconductor device according to claim 13, wherein
a width of the source connection line in the second direction is smaller than a width of the first source electrode in the second direction and a width of the third source electrode in the second direction,
a width of each of the first via hole and the second via hole in the first direction is smaller than a width thereof in the second direction, and
the width of the source connection line in the first direction is larger than the width of the source connection line in the second direction.

15. The semiconductor device according to claim 13, wherein
when viewed in the thickness direction, a number of third via holes to be connected to the source connection line and including the third via hole is larger than a number of first via holes to be connected to the first source electrode and including the first via hole and is larger than a number of second via holes to be connected to the third source electrode and including the second via hole.
